(19) United States
(12) Patent Application Publication
(10) Pub. No.: US 2017/0351279 A1
(43) Pub. Date: Dec. 7, 2017

(54) ELECTRONIC DEVICE AND PROCESSOR CONTROL METHOD

(71) Applicant: FUJITSU LIMITED, Kawasaki-shi (JP)

(72) Inventor: Masatoshi Ishii, Kawasaki (JP)

(73) Assignee: FUJITSU LIMITED, Kawasaki-shi (JP)

(21) Appl. No.: 15/601,021

(22) Filed: May 22, 2017

(30) Foreign Application Priority Data
Jun. 7, 2016 (JP) 2016-113787

(51) Int. Cl. G05D 23/24; G06F 3/06; G06F 13/16; G06F 17/18; G11C 11/401; H05K 5/00

(52) U.S. Cl. CPC G05D 23/24; G06F 17/18; G11C 11/401; G06F 3/0679; G06F 13/1694; H05K 5/0091

(57) ABSTRACT

An electronic device calculates a temperature index value of a temperature of a housing surface by using a temperature sensor and calculates a prediction reached value from change of the temperature index value. The electronic device calculates a rate parameter indicating a target of a decrease rate for decreasing the prediction reached value, on the basis of the prediction reached value calculated at a certain time point and a threshold value. The electronic device controls a clock frequency of a processor on the basis of the calculated rate parameter and correspondence information that associates a plurality of target values of the prediction reached value and a plurality of clock frequencies of the processor.

### CROSS-REFERENCE TO RELATED APPLICATION

This application is based upon and claims the benefit of priority of the prior Japanese Patent Application No. 2016-113787, filed on Jun. 7, 2016, the entire contents of which are incorporated herein by reference.

### FIELD

The embodiments discussed herein relate to an electronic device and a processor control method.

### BACKGROUND

Currently, electronic devices, such as a smartphone and a tablet terminal, are becoming widespread and are making progress in multi-functionalization and performance improvement. The heat generation amount of a processor provided in an electronic device increases with such multi-functionalization and performance improvement. On the other hand, it is not easy to increase the cooling capacity of the electronic device, due to shape restriction. Hence, when the processor operates under a high load for a long time, the processor is not cooled enough, and heat is transferred from the processor to a housing surface so as to increase a surface temperature, in some cases.

As a clock frequency becomes higher, the heat generation amount of the processor becomes larger, in many cases. In a conceivable solution, the processor is configured to be operable at a plurality of clock frequencies, and the electronic device restricts the clock frequency in such a manner that the surface temperature does not exceed a threshold value. However, the processor heat transfers to the housing surface after a delay, and even if the clock frequency is rapidly reduced, the surface temperature does not stop rising immediately. Thus, when there is a possibility that the surface temperature starts rising and exceeds the threshold value, the electronic device restricts the clock frequency before the surface temperature exceeds the threshold value, in some cases.

For example, a dynamic temperature control device that controls the clock frequency of the processor is proposed. The proposed dynamic temperature control device includes a sensor that measures a heat source temperature, another sensor that measures a circumference temperature, and a controller that restricts the clock frequency of the processor. The controller estimates the highest temperature expected to be reached when the current clock frequency continues, from the heat source temperature, the circumference temperature, and a predetermined calculation formula. When the estimated highest reached temperature exceeds a threshold value, the controller lowers the clock frequency to a level at which the highest reached temperature does not exceed the threshold value.

See, for example, Japanese Laid-open Patent Publication No. 2012-74064.

In a steady state in which the surface temperature is stabilized by the restriction of the clock frequency, the surface temperature converges around the threshold value, and the clock frequency of the processor is expected to be at a certain level corresponding to the threshold value of the surface temperature. However, there is a problem of how to control the clock frequency during a transient state from the temperature rising start to the steady state of the surface temperature.

A heat capacity exists between the processor and the housing surface, and thus it is possible that, even if the clock frequency is not rapidly reduced to a level corresponding to the steady state, the surface temperature does not exceed the threshold value. On the contrary, it is concerned that the processor performance decreases excessively, if the clock frequency is immediately reduced to the level corresponding to the steady state when a possibility of the surface temperature exceeding the threshold value is detected, as in the technology described in above Japanese Laid-open Patent Publication No. 2012-74064.

### SUMMARY

According to one aspect, there is provided an electronic device including: a memory; a temperature sensor; a housing that contains the temperature sensor; and a controller connected to the memory, contained in the housing, including a processor capable of operating at a plurality of clock frequencies, and configured to perform a procedure including: calculating a temperature index value of a temperature of a surface of the housing by using the temperature sensor, and calculating a prediction reached value that the temperature index value is predicted to reach a certain amount of time or more later from change of the calculated temperature index value, calculating a rate parameter indicating a target of a decrease rate for decreasing the prediction reached value, based on the prediction reached value calculated at a certain time point and a threshold value of the temperature index value, and controlling a clock frequency of the processor before the certain amount of time elapses, based on the calculated rate parameter and correspondence information that associates a plurality of target values of the prediction reached value and the plurality of clock frequencies.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 illustrates an example of an electronic device of a first embodiment;

FIG. 2 is a block diagram illustrating exemplary hardware of a portable terminal device;

FIG. 3 is a block diagram illustrating exemplary hardware of a design apparatus;

FIG. 4 illustrates an exemplary arrangement of heat sources and temperature sensors;

FIG. 5 illustrates an example of a heat circuit model that exhibits a transient response of heat conduction;

FIG. 6 illustrates an example of heat conduction from a plurality of heat sources;

FIG. 7 is a graph illustrating first exemplary change of relative temperatures of a plurality of temperature sensors;

FIG. 8 is a graph illustrating second exemplary change of relative temperatures of a plurality of temperature sensors;

FIG. 9 illustrates an example of an intermediate parameter table;

FIG. 10 illustrates an example of a parameter table;

FIG. 11 is a graph indicating an estimation example of relative temperatures of a plurality of heat sources;

FIG. 12 illustrates an example of a past data table;

FIG. 13 is a graph indicating an estimation example of contribution to a housing surface from heat sources;

FIG. 14 is a graph indicating an estimation example of a surface temperature;

FIG. 15 illustrates an example of a correspondence information table;

FIG. 16 is a block diagram illustrating exemplary functions of a portable terminal device and a design apparatus;

FIG. 17 is a flowchart illustrating an exemplary procedure of parameter decision;

FIG. 18 is a flowchart illustrating an exemplary procedure of heat source control;

FIG. 19 is a graph illustrating exemplary change of Tₛₐₜ(t) and T_{surf-1}(t) corresponding to a plurality of values of α;

FIG. 20 is a graph illustrating exemplary change of Tₛₐₜ(t) and T_{surf 1}(t) when a rate parameter is not used; and

FIG. 21 illustrates a control example of a surface temperature of a housing.

### DESCRIPTION OF EMBODIMENTS

Several embodiments will be described below with reference to the accompanying drawings, wherein like reference numerals refer to like elements throughout.

### First Embodiment

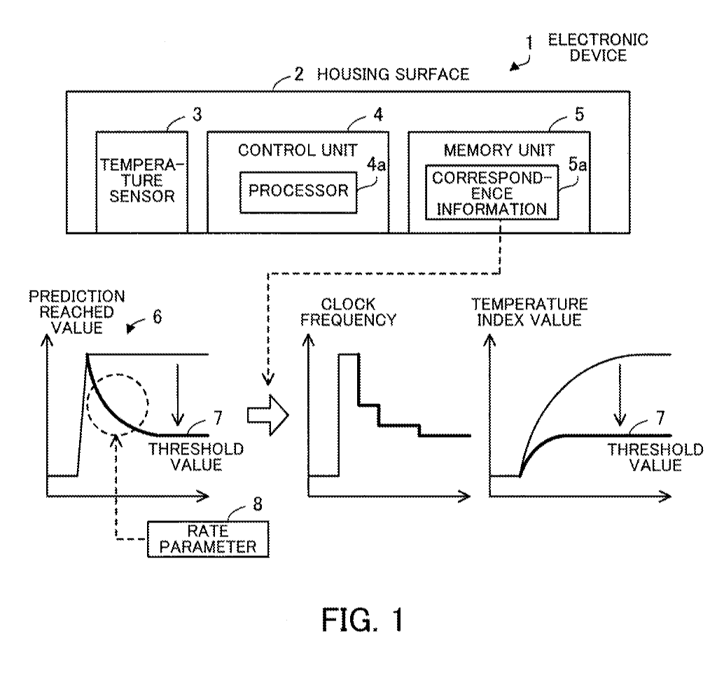

A first embodiment will be described. FIG. 1 illustrates an example of an electronic device of the first embodiment.

The electronic device 1 of the first embodiment has a housing surface 2 which is touched by a person. The electronic device 1 is a portable terminal device, such as a smartphone, a mobile phone, a tablet terminal, and a notebook computer. The electronic device 1 restricts a clock frequency of a processor 4a to prevent the temperature of the housing surface 2 from rising too high, in some cases.

The electronic device 1 includes a temperature sensor 3, a control unit 4, and a memory unit 5. The temperature sensor 3, the control unit 4, and the memory unit 5 are located inside the housing of the electronic device 1, for example. The temperature sensor 3, the control unit 4, and the memory unit 5 may be located on a substrate inside the housing. The control unit 4 includes the processor 4a. The memory unit 5 may be integrated in the control unit 4.

The temperature sensor 3 is a sensor device that measures a temperature at a position where the temperature sensor 3 is located. The temperature sensor 3 is a thermistor, for example. The electronic device 1 may be provided with a plurality of temperature sensors located at different positions, including the temperature sensor 3.

The processor 4a is a computing device capable of operating at a plurality of clock frequencies. The processor 4a is a central processing unit (CPU), a digital signal processor (DSP), or a graphics processing unit (GPU), for example. The control unit 4 may include another processor and may include an application specific electronic circuit, such as an application specific integrated circuit (ASIC) and a field programmable gate array (FPGA). The control unit 4 controls the clock frequency of the processor 4a by using the processor 4a, another processor, or another electronic circuit. When the processor 4a or another processor is used, the control unit 4 may execute a processor control program that describes a below procedure. The processor control program is stored in the memory unit 5 or another memory device.

The memory unit 5 stores correspondence information 5a. The memory unit 5 may be a volatile semiconductor memory, such as a random access memory (RAM), or may be a non-volatile storage, such as a flash memory. The correspondence information 5a will be described later.

The control unit 4 calculates a temperature index value of the temperature of the housing surface 2 by using the temperature sensor 3. The temperature index value indicates a temperature difference between the temperature of the housing surface 2 and a reference temperature, for example. The reference temperature is an outside air temperature around the electronic device 1, for example. Note that the electronic device 1 may include a plurality of heat sources including the processor 4a. In that case, the control unit 4 may separately estimate a temperature difference generated by heat generation of the processor 4a, which is part of the temperature difference between the temperature of the housing surface 2 and the reference temperature, by using a plurality of temperature sensors of different positions.

The control unit 4 calculates a prediction reached value 6 that the temperature index value is predicted to reach a certain amount of time or more later, from temporal change of the calculated temperature index value. The prediction reached value 6 indicates the highest value that is reached when a current change tendency of the temperature index value continues, for example. For example, the control unit 4 calculates the prediction reached value 6 from the temperature index value at a certain time point, an increase amount of the temperature index value per unit time, and a predetermined estimation equation. The control unit 4 may further use a delay parameter (for example, a thermal time constant) indicating delay of heat transfer from the processor 4a to the housing surface 2 in order to calculate the prediction reached value 6.

The control unit 4 calculates a rate parameter 8 indicating a target decrease rate for decreasing the prediction reached value 6 on the basis of the prediction reached value 6 calculated at a certain time point and a threshold value 7 of the temperature index value. The control unit 4 may calculate the rate parameter 8 only when the prediction reached value 6 calculated at the certain time point is larger than the threshold value 7. The rate parameter 8 is a time constant indicating a rate at which the prediction reached value 6 converges to the threshold value 7, for example. The control unit 4 may further use the delay parameter indicating delay of heat transfer from the processor 4a to the housing surface 2 in order to calculate the rate parameter 8. For example, the control unit 4 calculates a decrease rate a by dividing the threshold value 7 by the prediction reached value 6 and calculates the rate parameter 8 which is a product of α and the thermal time constant from the processor 4a to the housing surface 2.

The threshold value 7 is a temperature index value corresponding to an allowable heat generation amount for the processor 4a. For example, the control unit 4 calculates the temperature of the housing surface 2 at a certain time point and decides the threshold value 7 on the basis of the temperature difference (increase margin amount) between a predetermined allowable temperature and the calculated temperature of the housing surface 2 and the temperature index value at the certain time point. When the electronic device 1 includes a plurality of heat sources, the control unit 4 decides the threshold value 7 by adding the increase margin amount to a temperature difference generated by heat generation of the processor 4a, for example.

The control unit 4 controls the clock frequency of the processor 4a before a certain amount of time elapses, on the basis of the correspondence information 5a and the rate parameter 8. The correspondence information 5a associates a plurality of target values of the prediction reached value 6 with a plurality of clock frequencies of the processor 4a. A certain target value is reached by the temperature index value when the processor 4a continues operating at a certain clock frequency, for example. The correspondence information 5a may be generated in advance and written into the electronic device 1. The control unit 4 lowers the upper limit of the clock frequency of the processor 4a in a phased manner such that the prediction reached value 6 decreases at a decrease rate according to the rate parameter 8 with elapse of time, for example. For example, the control unit 4 decides the target value of the prediction reached value 6 of a predetermined time later on the basis of the rate parameter 8, and sets the upper limit at the clock frequency associated with the decided target value.

Here, when time elapses sufficiently and the electronic device 1 reaches a steady state, it is expected that the temperature of the housing surface 2 stops rising, and that the calculated temperature index value converges to the threshold value 7. In this case, it is expected that the prediction reached value 6 converges to the threshold value 7, and that the clock frequency of the processor 4a or its upper limit converges to a level corresponding to the threshold value 7. On the other hand, in a transient state in which the temperature of the housing surface 2 is rising, the clock frequency of the processor 4a is restricted in accordance with a decrease rate indicated by the rate parameter 8 and does not necessarily decrease to the level corresponding to the threshold value 7 rapidly.

According to the electronic device 1 of the first embodiment, the temperature index value of the temperature of the housing surface 2 is calculated by using the temperature sensor 3, and the prediction reached value 6 which the temperature index value is predicted to reach a certain amount of time or more later is calculated. The rate parameter 8 indicating the target of the decrease rate at which to decrease the prediction reached value 6 is calculated on the basis of the prediction reached value 6 calculated at a certain time point and the threshold value 7. The clock frequency of the processor 4a is controlled on the basis of the calculated rate parameter 8 and the correspondence information 5a that associates a plurality of target values of the prediction reached value 6 with a plurality of clock frequencies.

Thereby, the clock frequency is needless to be restricted excessively as compared with a case in which the clock frequency is rapidly decreased to the level corresponding to the threshold value 7 when the prediction reached value 6 exceeds the threshold value 7. That is, when the heat capacity between the processor 4a and the housing surface 2 is taken into consideration, even if the clock frequency exceeds the level corresponding to the threshold value 7 temporarily in the transient state, the subsequent temperature index value does not exceed the threshold value 7 in some cases, and thus there is much time to converge the clock frequency. The restriction of the clock frequency is made gradual by utilizing this transient state, and thereby the clock frequency is needless to be restricted excessively, and the performance of the processor 4a is prevented from decreasing.

### Second Embodiment

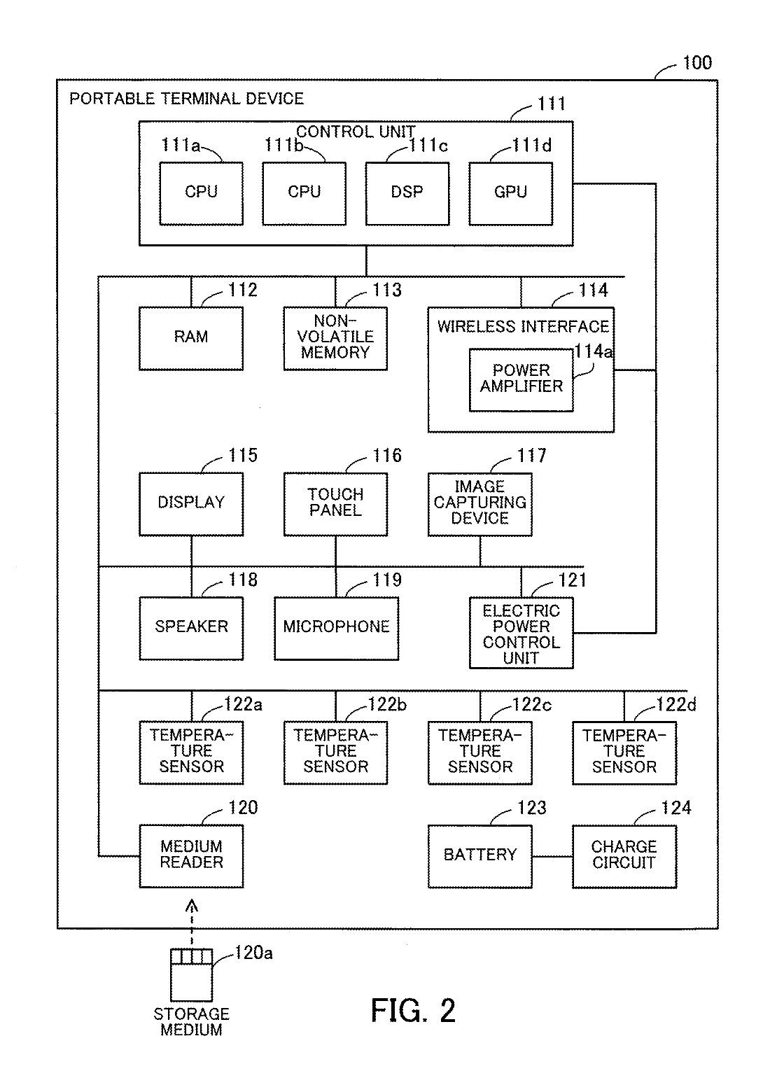

Next, a second embodiment will be described. FIG. 2 is a block diagram illustrating exemplary hardware of a portable terminal device.

The portable terminal device 100 of the second embodiment has a surface which is touched by a user. The portable terminal device 100 is a smartphone, a mobile phone, a tablet terminal, or a notebook computer, for example. Note that the portable terminal device 100 corresponds to the electronic device 1 of the first embodiment.

The portable terminal device 100 includes a control unit 111, a RAM 112, a non-volatile memory 113, a wireless interface 114, a display 115, a touch panel 116, an image capturing device 117, a speaker 118, a microphone 119, and a medium reader 120. Also, the portable terminal device 100 includes an electric power control unit 121, temperature sensors 122a, 122b, 122c, and 122d, a battery 123, and a charge circuit 124.

The control unit 111 controls the portable terminal device 100. The control unit 111 includes CPUs 111a and 111b, a DSP 111c, and a GPU 111d.

Each of the CPUs 111a and 111b is a processor that includes a computation circuit that executes commands of programs. Each of the CPUs 111a and 111b loads at least a part of the programs and data stored in the non-volatile memory 113 into the RAM 112, and executes the programs. Each of the CPUs 111a and 111b may include a plurality of CPU cores. A procedure of the second embodiment may be executed in parallel by using the CPUs or the CPU cores.

The DSP 111c processes digital signals. For example, the DSP 111c processes a transmission signal transmitted from the wireless interface 114 and a reception signal received by the wireless interface 114. Also, for example, the DSP 111c processes an audio signal output to the speaker 118 and an audio signal input from the microphone 119. The GPU 111d processes an image signal. For example, the GPU 111d generates an image to be displayed on the display 115.

The RAM 112 is a volatile semiconductor memory that temporarily stores the programs executed by the CPUs 111a and 111b and the data used in computation. This data includes the correspondence information. The correspondence information associates a plurality of target values of a prediction reached value which the temperature index value of the housing surface temperature of the portable terminal device 100 is predicted to reach a certain amount of time or more later, with a plurality of clock frequencies of the processor. The processor is one or more of the CPUs 111a and 111b, the DSP 111c, and the GPU 111d. Note that the portable terminal device 100 may include a memory of a type other than the RAM 112 and may include a plurality of memories.

The non-volatile memory 113 is a non-volatile memory device that stores software programs, such as an operating system (OS), middleware, and application software, as well as data. The programs include a surface temperature calculation program for estimating the surface temperature of the portable terminal device 100 and a processor control program for controlling the clock frequency of the processor. The non-volatile memory 113 is a flash memory or a solid state drive (SSD), for example. Note that the portable terminal device 100 may include a non-volatile memory device of another type, such as a hard disk drive (HDD).

The wireless interface 114 is a communication interface for communicating with other communication devices, such as a base station and an access point, via a wireless link. Note that the portable terminal device 100 may include a wired interface for communicating with other communication devices, such as a switch and a router, via a wired cable. The wireless interface 114 includes an electric power amplifier 114a that amplifies a transmission signal. The electric power amplifier 114a is sometimes simply referred to as an amplifier and is sometimes referred to as a high power amplifier (HPA).

The display 115 displays an image in accordance with a command from the control unit 111. For example, a liquid crystal display (LCD), an organic electro-luminescence (OEL) display, or the like is used as the display 115.

The touch panel 116 is located over the display 115. The touch panel 116 detects touch operation of the user on the display 115. The touch panel 116 detects a position touched by a finger or a touch pen and reports the detected position to the control unit 111. For example, a matrix switch method, a resistance film method, a surface acoustic wave method, an infrared light method, an electromagnetic induction method, an electrostatic capacitance method, or the like is used as a position detection method. Note that the portable terminal device 100 may include another input device, such as a keypad. For example, the keypad includes one or two or more input keys. The keypad detects user's pressing of an input key and reports the pressed input key to the control unit 111.

The image capturing device 117 captures a still image or a moving image. For example, a charge coupled device (CCD) sensor, a complementary metal oxide semiconductor (CMOS) sensor, or the like is used as an image sensor. The image capturing device 117 stores image data of a captured image in the RAM 112 or the non-volatile memory 113.

The speaker 118 acquires an electrical signal as an audio signal from the control unit 111 and reproduces sound by converting the electrical signal to a physical signal. For example, when the user talks through a telephone, voice of an opposite-end person and background noise are reproduced. The microphone 119 converts a physical sound signal to an electrical signal and outputs the electrical signal as an audio signal to the control unit 111. For example, when the user talks through a telephone, voice of the user and background noise are input from the microphone 119.

The medium reader 120 is a reader device that reads programs and data recorded in a storage medium 120a. The storage medium 120a is, for example, a flash memory, a magnetic disk such as a flexible disk (FD) and an HDD, an optical disc such as a compact disc (CD) and a digital versatile disc (DVD), a magneto-optical disk (MO), or the like. The medium reader 120 stores the programs and data read from the storage medium 120a in the RAM 112 or the non-volatile memory 113.

The electric power control unit 121 controls electric power consumption of the control unit 111 and the wireless interface 114 by changing operation levels of the control unit 111 and the wireless interface 114. As the operation level becomes higher, the electric power consumption becomes larger, and the heat generation amount becomes larger. For example, the electric power control unit 121 changes the clock frequency of the CPUs 111a and 111b. As the clock frequency becomes higher, the computing powers of the CPUs 111a and 111b becomes greater, and the electric power consumption and the heat generation amount become larger. Also, for example, the electric power control unit 121 changes the communication rate of the wireless interface 114. As the communication rate becomes higher, the electric power consumption and the heat generation amount of the electric power amplifier 114a become larger.

Each of the temperature sensors 122a, 122b, 122c, and 122d measures a temperature at a position where the temperature sensor is located. Thermistors are used as the temperature sensors 122a, 122b, 122c, and 122d, for example. The temperature sensor 122a is located near the CPU 111a. The temperature sensor 122b is located near the charge circuit 124. The temperature sensor 122c is located near the electric power amplifier 114a. The temperature sensor 122d is located near the battery 123. The temperature sensors 122a, 122b, 122c, and 122d report measured temperatures to the control unit 111.

The battery 123 is a secondary battery that is chargeable and dischargeable repeatedly. The charge circuit 124 accumulates electrical energy in the battery 123. The battery 123 supplies the accumulated electrical energy to components of the portable terminal device 100. For example, the battery 123 supplies the electrical energy to the CPUs 111a and 111b and the wireless interface 114. The charge circuit 124 acquires the electrical energy from an external power supply located outside the portable terminal device 100 and charges the battery 123 with the electrical energy. The charge circuit 124 charges the battery 123 with the electrical energy when the portable terminal device 100 is connected to the external power supply.

Here, it is possible that the user touches the surface of the portable terminal device 100, and thus it is preferable that the surface temperature of the portable terminal device 100 do not become too high. Thus, the portable terminal device 100 estimates the surface temperature by using the temperature sensors 122a, 122b, 122c, and 122d. An estimation equation for estimating the surface temperature is generated by a design apparatus in advance and is stored in the portable terminal device 100.

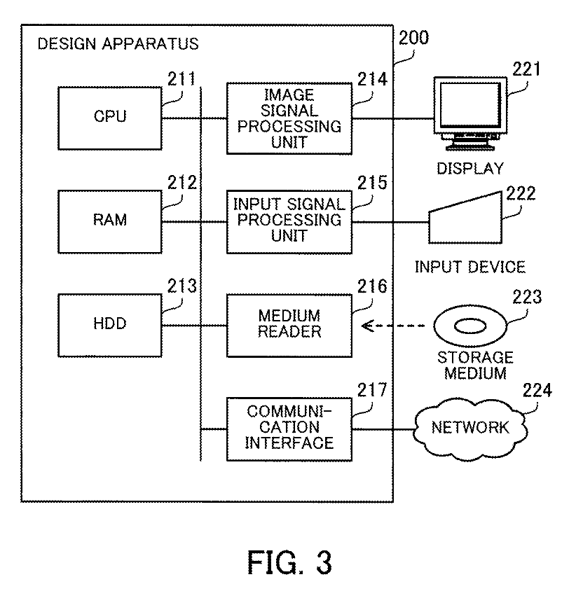

FIG. 3 is a block diagram illustrating exemplary hardware of a design apparatus. The design apparatus 200 of the second embodiment generates an estimation equation used in estimating the surface temperature of the portable terminal device 100. The estimation equation generated by the design apparatus 200 is stored in the non-volatile memory 113 of the portable terminal device 100 in advance. Note that the estimation equation may be transmitted from the design apparatus 200 or another device to the portable terminal device 100 via a network. The design apparatus 200 may be a client apparatus, such as a client computer operated by the user, and may be a server apparatus, such as a server computer. The design apparatus 200 includes a CPU 211, a RAM 212, an HDD 213, an image signal processing unit 214, an input signal processing unit 215, a medium reader 216, and a communication interface 217.

The CPU 211 is a processor that includes a computation circuit that executes commands of programs. The CPU 211 loads into the RAM 212 at least a part of programs and data stored in the HDD 213 and executes the programs. The RAM 212 is a volatile semiconductor memory for temporarily storing the programs executed by the CPU 211 and the data that the CPU 211 uses in computation. The HDD 213 is a non-volatile memory device that stores software programs, such as an OS, middleware, and application software, and data. Note that the design apparatus 200 may include a memory device of another type, such as a flash memory and an SSD.

The image signal processing unit 214 outputs an image to a display 221 connected to the design apparatus 200 in accordance with a command from the CPU 211. The input signal processing unit 215 acquires an input signal from an input device 222 connected to the design apparatus 200 and outputs the input signal to the CPU 211. The input device 222 may be a pointing device, such as a mouse, a touch panel, and a touch pad, a keyboard, a remote controller, a button switch, or the like. Also, a plurality of types of input devices may be connected to the design apparatus 200.

The medium reader 216 is a reader device that reads programs and data recorded in a storage medium 223. The storage medium 223 is a magnetic disk such as a flexible disk and an HDD, an optical disc such as a CD and a DVD, a magneto-optical disk, or a semiconductor memory, for example. The medium reader 216 stores the programs and data read from the storage medium 223 in the RAM 212 or the HDD 213, for example.

The communication interface 217 is connected to a network 224 and communicate with other devices via the network 224. The communication interface 217 may be a wired communication interface connected by a cable and a communication element such as a switch, or may be a wireless communication interface connected by a wireless link with a base station.

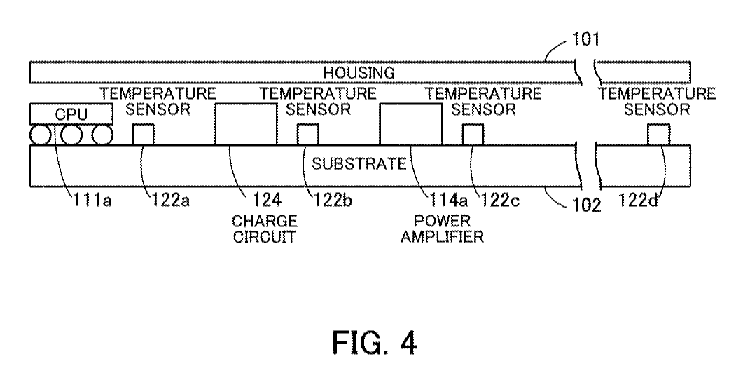

Next, heat transfer in the portable terminal device 100 will be described. FIG. 4 illustrates an exemplary arrangement of the heat sources and the temperature sensors.

The portable terminal device 100 includes a housing 101 and a substrate 102. The housing 101 surrounds the components of the portable terminal device 100. The outside of the housing 101 may be touched by the user. The substrate 102 is located inside the housing 101. At least some of the components of the portable terminal device 100 are located on the substrate 102. Lines (for example, copper lines) that electrically connect two or more components are formed on the substrate 102.

The CPU 111a, the charge circuit 124, and the electric power amplifier 114a are located on the substrate 102. The CPU 111a, the charge circuit 124, and the electric power amplifier 114a are components that generate comparatively large amounts of heat and may be referred to as heat sources. The temperature sensors 122a, 122b, and 122c are located on the substrate 102 beside these heat sources. The temperature sensor 122a is at the closest position to the CPU 111a among the heat sources. The temperature sensor 122b is at the closest position to the charge circuit 124 among the heat sources. The temperature sensor 122c is at the closest position to the electric power amplifier 114a among the heat sources.

Also, the portable terminal device 100 includes the temperature sensor 122d that measures a reference point temperature. The temperature sensor 122d is sufficiently away from the heat sources, i.e., the CPU 111a, the charge circuit 124, and the electric power amplifier 114a as compared with the temperature sensors 122a, 122b, and 122c.

The temperature change of the heat sources takes a sufficiently longer delay time to influence the measured temperature of the temperature sensor 122d than to influence the measured temperatures of the temperature sensors 122a, 122b, and 122c. That is, a thermal time constant, described later, of the temperature sensor 122d is sufficiently larger than those of the temperature sensors 122a, 122b, and 122c. The temperature sensor 122d may be located on the substrate 102 or may be located at a site other than the substrate 102. In the second embodiment, the temperature sensor 122d is located near the battery 123, for example.

The heat of the CPU 111a transfers to the temperature sensors 122a, 122b, and 122c via the substrate 102. The temperature sensor 122a is closest to the CPU 111a, and thus the heat of the CPU 111a has the largest influence on the measured temperature of the temperature sensor 122a. In the same way, the heat of the charge circuit 124 transfers to the temperature sensors 122a, 122b, and 122c via the substrate 102. The temperature sensor 122b is closest to the charge circuit 124, and thus the heat of the charge circuit 124 has the largest influence on the measured temperature of the temperature sensor 122b. The heat of the electric power amplifier 114a transfers to the temperature sensors 122a, 122b, and 122c via the substrate 102. The temperature sensor 122c is closest to the electric power amplifier 114a, and thus the heat of the electric power amplifier 114a has the largest influence on the measured temperature of the temperature sensor 122c.

Also, the heat of the CPU 111a, the charge circuit 124, and the electric power amplifier 114a transfers to the surface of the housing 101 via a tangible object or a space that exists between the substrate 102 and the housing 101. The position of the highest surface temperature on the surface of the housing 101 depends on a combination of the heat generation amounts of the CPU 111a, the charge circuit 124, and the electric power amplifier 114a. Thus, the position of the highest surface temperature is not fixed but changes according to a situation of how the components are used.

Note that the CPU 111a corresponds to the processor 4a of the first embodiment. The temperature sensor 122a corresponds to the temperature sensor 3 of the first embodiment.

Here, first, a heat transfer model in the case of only one heat source on the substrate 102 will be described. In this case, the heat generation amounts of the charge circuit 124 and the electric power amplifier 114a are small enough to be disregarded, and the heat source is the CPU 111a only, for example.

The heat of the CPU 111a of the heat source transfers to the temperature sensor 122a. The heat gradually transfers from the CPU 111a to the temperature sensor 122a, and thus a transient response as a non-steady state occurs in the measured temperature of the temperature sensor 122a. Also, the heat of the CPU 111a of the heat source transfers to the surface of the housing 101. The heat gradually transfers from the CPU 111a to the surface of the housing 101, and thus a transient response as a non-steady state occurs in the surface temperature of the housing 101. Here, a heat transfer model that considers both of the transient response from the CPU 111a to the temperature sensor 122a and the transient response from the CPU 111a to the housing 101 will be considered.

The measured temperature of the temperature sensor 122a is defined as formula (1). Tₛₑₙₛₒᵣ₁(s) is obtained by converting a relative temperature of the temperature sensor 122a relative to the reference point temperature of the temperature sensor 122d to a frequency domain by using Laplace transform. The relative temperature is calculated by subtracting the measured temperature (reference point temperature) of the temperature sensor 122d from the measured temperature of the temperature sensor 122a. In the following, a variable in the time domain is sometimes denoted by “t”, and a variable in the frequency domain is sometimes denoted by “s”. T_{cpu}(s) is obtained by Laplace transforming the relative temperature of the CPU 111a. H(s) is a transfer function in the frequency domain for converting the relative temperature of the CPU 111a to the relative temperature of the temperature sensor 122d. H(s) is a transfer function that considers the transient response, and includes h and τₕ as parameters. The h is a heat transfer coefficient, and τₕ is a thermal time constant. The values of h and τₕ are calculated in advance by using the design apparatus 200. For example, h is equal to 0.500, and τₕ is equal to 40.

$${T}_{sensor 1} ( s ) = H ( s ) {T}_{cpu} ( s ) where H ( s ) = \frac{h}{1 + s {τ}_{h}} \qquad ( 1 )$$

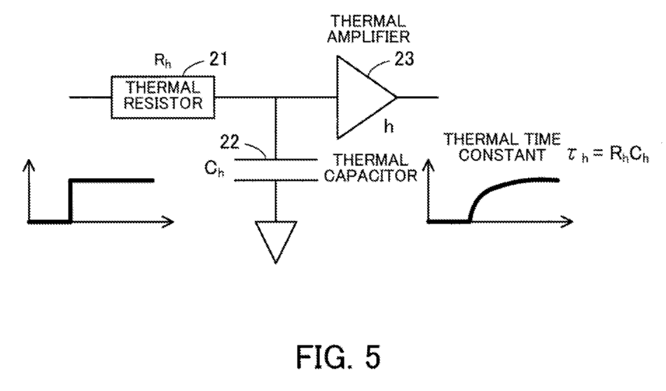

FIG. 5 illustrates an example of a heat circuit model that exhibits a transient response of heat conduction. The transfer function H(s) is derived from the heat circuit model illustrated in FIG. 5. This heat circuit model is provided between the CPU 111a and the temperature sensor 122a. The heat circuit model includes a thermal resistor 21, a thermal capacitor 22, and a thermal amplifier 23. The value of the thermal resistor 21 is Rₕ. The value of the thermal capacitor 22 is Cₕ. The product of Rₕ and Cₕ is the thermal time constant τₕ. The amplification factor of the thermal amplifier 23 is h. An input of the thermal resistor 21 is an input of the heat circuit model. An output of the thermal resistor 21 is connected to an input of the thermal capacitor 22 and an input of the thermal amplifier 23. An output of the thermal capacitor 22 is connected to an earth. An output of the thermal amplifier 23 is an output of the heat circuit model.

When the input of the thermal resistor 21 changes from “0” to “1” rapidly, the output of the thermal amplifier 23 changes from “0” to “h”. However, the output of the thermal amplifier 23 does not change from “0” to “h” rapidly but changes gradually. The delay time that it takes for the output of the thermal amplifier 23 to get close to “h” sufficiently since its start of change is the thermal time constant τₕ. Thus, the measured temperature of the temperature sensor 122a becomes higher as the heat transfer coefficient h becomes larger, and becomes lower as the heat transfer coefficient h becomes smaller. Also, when the heat generation amount of the CPU 111a changes, the change rate of the measured temperature of the temperature sensor 122a becomes faster as the thermal time constant τₕ becomes smaller, and becomes slower as the thermal time constant τₕ becomes larger.

The heat transfer from the CPU 111a to the housing 101 may be modeled by using the same heat circuit model as the heat transfer from the CPU 111a to the temperature sensor 122a. Note that values of parameters, such as a heat transfer coefficient and a thermal time constant, differ between the former and the latter.

The surface temperature of the housing 101 is defined as formula (2). T_{surface}(s) is obtained by converting a relative temperature of the housing 101 relative to the reference point temperature to the frequency domain by Laplace transform. T_{cpu}(s) is obtained by Laplace transforming the relative temperature of the CPU 111a. G(s) is a transfer function in the frequency domain for converting the relative temperature of the CPU 111a to the relative temperature of the housing 101. G(s) is a transfer function that considers the transient response, and includes g and τ_{g} as parameters. The g is a heat transfer coefficient, and τ_{g} is a thermal time constant. The values of g and τ_{g} are calculated in advance by using the design apparatus 200. For example, g is equal to 0.425, and τ_{g} is equal to 85.

$${T}_{surface} ( s ) = G ( s ) {T}_{cpu} ( s ) where G ( s ) = \frac{g}{1 + s {τ}_{g}} \qquad ( 2 )$$

The surface temperature of the housing 101 is defined as formula (3) from formula (1) and formula (2). T_{surface}(s) in formula (3) is a relative temperature of the housing 101 in the frequency domain. Thus, the surface temperature of the housing 101 at a certain time point is defined as formula (4) by using inverse Laplace transform. T_{surface}(t) is a surface temperature of the housing 101 at a time point t. Tₛₑₙₛₒᵣ₂(t) is a reference point temperature at a time point t which is measured by the temperature sensor 122d. T_{surface}(t) is calculated by adding Tₛₑₙₛₒᵣ₂(t) to a value obtained by inverse Laplace transforming T_{surface}(s).

$$\begin{matrix}{T}_{surface} ( s ) = \frac{G ( s )}{H ( s )} {T}_{sensor 1} ( s ) = \frac{g}{h} \frac{1 + s {τ}_{h}}{1 + s {τ}_{g}} {T}_{sensor 1} ( s ) & ( 3 ) \\ {T}_{surface} ( t ) = {ℒ}^{- 1} ( \frac{g}{h} \frac{1 + s {τ}_{h}}{1 + s {τ}_{g}} {T}_{sensor 1} ( s ) ) + {T}_{sensor 2} ( t ) & ( 4 )\end{matrix}$$

Formula (4) is transformed to formula (5) by developing the inverse Laplace transform into a difference equation. The first term of the right side of formula (5) is the relative temperature of the temperature sensor 122a, which is obtained by subtracting the reference point temperature from the measured temperature of the temperature sensor 122a. The second term of the right side is the relative temperature of time Δt before of the temperature sensor 122a, which is obtained by subtracting the reference point temperature of time Δt before from the measured temperature of time Δt before of the temperature sensor 122a. At is a measurement cycle and is set to approximately 10 seconds, for example. t−Δt means the last measurement time.

$${T}_{surface} ( t ) = {a}_{0} ( {T}_{sensor 1} ( t ) - {T}_{sensor 2} ( t ) ) + {a}_{1} ( {T}_{sensor 1} ( t - Δ t ) - {T}_{sensor 2} ( t - Δ t ) ) - {b}_{1} ( {T}_{surface} ( t - Δ t ) - {T}_{sensor 2} ( t - Δ t ) ) + {T}_{sensor 2} ( t ) \\ where {a}_{0} = \frac{g}{h } \frac{Δ t + {2}_{{τ}_{h}}}{Δ t + {2}_{{τ}_{g}}} {a}_{1} = \frac{g}{h } \frac{Δ t - {2}_{{τ}_{h}}}{Δ t + {2}_{{τ}_{g}}} \\ {b}_{1} = \frac{g}{h } \frac{Δ t - {2}_{{τ}_{g}}}{Δ t + {2}_{{τ}_{g}}} \qquad ( 5 )$$

The third term of the right side is the relative temperature of time Δt before of the housing 101, which is obtained by subtracting the reference point temperature of time Δt before from the surface temperature of time Δt before of the housing 101. The fourth term of the right side is the reference point temperature measured by the temperature sensor 122d. The first term of the right side is multiplied by a coefficient a₀; the second term of the right side is multiplied by a coefficient a₁; and the third term of the right side is multiplied by a coefficient b₁. The a₀, a₁, and b₁ are defined as in formula (5) by using h, g, τₕ, and τ_{g}. Thereby, the surface temperature of the housing 101 is estimated by using the measured temperatures of the temperature sensors 122a and 122d, the measured temperatures of the last time of the temperature sensors 122a and 122d, and the estimated value of the surface temperature of the last time of the housing 101.

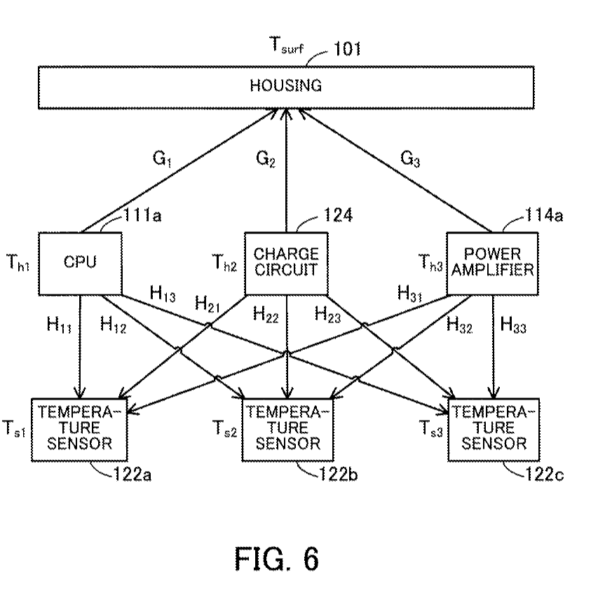

Next, the above heat transfer model is applied to a case including a plurality of heat sources. FIG. 6 illustrates an example of heat conduction from a plurality of heat sources.

The Laplace-transformed relative temperature of the CPU 111a is Tₕ₁(s). The heat of the CPU 111a transfers to the temperature sensor 122a via a transfer function H₁₁(s), transfers to the temperature sensor 122b via a transfer function H₁₂(s), and transfers to the temperature sensor 122c via a transfer function H₁₃(s). In the same way, the Laplace-transformed relative temperature of the charge circuit 124 is Tₕ₂(s). The heat of the charge circuit 124 transfers to the temperature sensor 122a via a transfer function H₂₁(s), transfers to the temperature sensor 122b via a transfer function H₂₂(s), and transfers to the temperature sensor 122c via a transfer function H₂₃(s). The Laplace-transformed relative temperature of the electric power amplifier 114a is Tₕ₃(s). The heat of the electric power amplifier 114a transfers to the temperature sensor 122a via a transfer function H₃₁(s), transfers to the temperature sensor 122b via a transfer function H₃₂(s), and transfers to the temperature sensor 122c via a transfer function H₃₃(s).

The Laplace-transformed relative temperature of the temperature sensor 122a is Tₛ₁(s). Tₛ₁(s) is a combination of contribution from the CPU 111a, contribution from the charge circuit 124, and contribution from the electric power amplifier 114a. Thus, Tₛ₁(s) is defined as formula (6). Hᵢⱼ(s) is a transfer function that expresses heat transfer from an i-th heat source to a j-th temperature sensor. hᵢⱼ is a heat transfer coefficient from an i-th heat source to a j-th temperature sensor, and τₕᵢⱼ is a thermal time constant from an i-th heat source to a j-th temperature sensor. The values of hᵢⱼ and τₕᵢⱼ are calculated in advance by using the design apparatus 200.

$${T}_{s 1} ( s ) = {H}_{11} ( s ) {T}_{h 1} ( s ) + {H}_{12} {T}_{h 2} ( s ) + {H}_{13} ( s ) {T}_{h 3} ( s ) where \\ {H}_{ij} ( s ) = \frac{{h}_{ij}}{1 + s {τ}_{hij}} \qquad ( 6 )$$

In the same way, the Laplace-transformed relative temperature of the temperature sensor 122b is Tₛ₂(s). Tₛ₂(s) is a combination of the contribution from the CPU 111a, the contribution from the charge circuit 124, and the contribution from the electric power amplifier 114a. The Laplace-transformed relative temperature of the temperature sensor 122c is Tₛ₃(s). Tₛ₃(s) is a combination of the contribution from the CPU 111a, the contribution from the charge circuit 124, and the contribution from the electric power amplifier 114a. Thus, Tₛ₁(s), Tₛ₂(s), and Tₛ₃(s) are expressed in a matrix form as in formula (7). A matrix H is a matrix of a transfer function. The element of i-th row and j-th column of the matrix H is Hᵢⱼ(s) that indicates heat transfer from an i-th heat source to a j-th temperature sensor.

$$[ \begin{matrix}{T}_{s 1} ( s ) \\ {T}_{s 2} ( s ) \\ {T}_{s 3} ( s )\end{matrix} ] = H [ \begin{matrix}{T}_{h 1} ( s ) \\ {T}_{h 2} ( s ) \\ {T}_{h 3} ( s )\end{matrix} ] = [ \begin{matrix}{H}_{11} ( s ) & {H}_{12} ( s ) & {H}_{13} ( s ) \\ {H}_{21} ( s ) & {H}_{22} ( s ) & {H}_{23} ( s ) \\ {H}_{31} ( s ) & {H}_{32} ( s ) & {H}_{33} ( s )\end{matrix} ] [ \begin{matrix}{T}_{h 1} ( s ) \\ {T}_{h 2} ( s ) \\ {T}_{h 3} ( s )\end{matrix} ] \qquad ( 7 )$$

Also, the heat of the CPU 111a transfers to the surface of the housing 101 via a transfer function G₁(s). The heat of the charge circuit 124 transfers to the surface of the housing 101 via a transfer function G₂(s). The heat of the electric power amplifier 114a transfers to the surface of the housing 101 via a transfer function G₃(s).

The Laplace-transformed relative temperature of the surface of the housing 101 is T_{surf}(s). T_{surf}(s) is a combination of the contribution from the CPU 111a, the contribution from the charge circuit 124, and the contribution from the electric power amplifier 114a. Thus, T_{surf}(s) is defined as formula (8). Gᵢ(s) is a transfer function that expresses the heat transfer from an i-th heat source to the housing 101. gᵢ is a heat transfer coefficient from an i-th heat source to the housing 101, and τ_{gi} is a thermal time constant from an i-th heat source to the housing 101. The values of gᵢ and τ_{gi} are calculated in advance by using the design apparatus 200.

$${T}_{surf} ( s ) = {G}_{1} ( s ) {T}_{h 1} ( s ) + {G}_{2} ( s ) {T}_{h 2} ( s ) + {G}_{3} ( s ) {T}_{h 3} ( s ) where \\ {G}_{i} ( s ) = \frac{{g}_{i}}{1 + s {τ}_{gi}} \qquad ( 8 )$$

Formula (8) may be expressed in a matrix form. When Tₕ₁(s), Tₕ₂(s), and Tₕ₃(s) are developed by using formula (7), T_{surf}(s) is expressed as the product of Gᵢ(s), the inverse matrix of H, and Tₛⱼ(s) as in formula (9). That is, the relative temperatures of the CPU 111a, the charge circuit 124, and the electric power amplifier 114a are estimated from the relative temperatures of the temperature sensors 122a, 122b, and 122c and the inverse matrix of H. Moreover, the surface temperature of the housing 101 is estimated from the relative temperatures of the CPU 111a, the charge circuit 124, and the electric power amplifier 114a, G₁(s), G₂(s), and G₃(s).

$${T}_{surf} ( s ) = {[ \begin{matrix}{G}_{1} ( s ) \\ {G}_{2} ( s ) \\ {G}_{3} ( s )\end{matrix} ]}^{T} [ \begin{matrix}{T}_{h 1} ( s ) \\ {T}_{h 2} ( s ) \\ {T}_{h 3} ( s )\end{matrix} ] = {[ \begin{matrix}{G}_{1} ( s ) \\ {G}_{2} ( s ) \\ {G}_{3} ( s )\end{matrix} ]}^{T} {H}^{- 1} [ \begin{matrix}{T}_{s 1} ( s ) \\ {T}_{s 2} ( s ) \\ {T}_{s 3} ( s )\end{matrix} ] \qquad ( 9 )$$

The inverse matrix of H is defined as formula (10). Note that the parameter s of each transfer function is omitted in formula (10). Δ is an eigenvalue and is equal to (H₁₁H₂₂−H₁₂H₂₁)H₃₃+(H₁₃H₂₁−H₁₁H₂₃)H₃₂+(H₁₂H₂₃−H₁₃H₂₂)H₃₁.

$${H}^{- 1} = \frac{1}{Δ} [ \begin{matrix}{H}_{22} {H}_{33} - {H}_{23} {H}_{32} & {H}_{13} {H}_{32} - {H}_{12} {H}_{33} & {H}_{12} {H}_{23} - {H}_{13} {H}_{22} \\ {H}_{23} {H}_{31} - {H}_{21} {H}_{33} & {H}_{11} {H}_{33} - {H}_{13} {H}_{31} & {H}_{11} {H}_{23} - {H}_{13} {H}_{21} \\ {H}_{21} {H}_{32} - {H}_{22} {H}_{31} & {H}_{12} {H}_{31} - {H}_{11} {H}_{32} & {H}_{11} {H}_{22} - {H}_{12} {H}_{21}\end{matrix} ] \qquad ( 10 )$$

Here, the transfer function Hᵢⱼ(s) in formula (10) includes the thermal time constant τₕᵢⱼ. Hence, there is a problem that the calculation amount of the product of the inverse matrix of H and the relative temperatures of the temperature sensors 122a, 122b, and 122c becomes enormous, and that the load of the portable terminal device 100 becomes too large. When T_{surf}(s) is calculated by formula (9), sixth order filter calculation is performed 9 times. In general, when there are n (n is an integer equal to or larger than 2) sets of heat sources and temperature sensors, 2n order filter calculation is performed n² times.

Thus, in the second embodiment, the portable terminal device 100 approximately calculates T_{surf}(s) by a method of a smaller calculation amount. Specifically, the portable terminal device 100 uses transfer functions that do not consider the transient response on the substrate 102, when estimating the heat source temperatures of the CPU 111a, the charge circuit 124, and the electric power amplifier 114a from the measured temperatures of the temperature sensors 122a, 122b, and 122c. Then, the portable terminal device 100 uses transfer functions that consider the transient response from the substrate 102 to the housing 101 as well as the transfer delay on the substrate 102, when estimating the surface temperature of the housing 101 from the heat source temperatures of the CPU 111a, the charge circuit 124, and the electric power amplifier 114a. This approximation calculation utilizes the following characteristics of heat transfer.

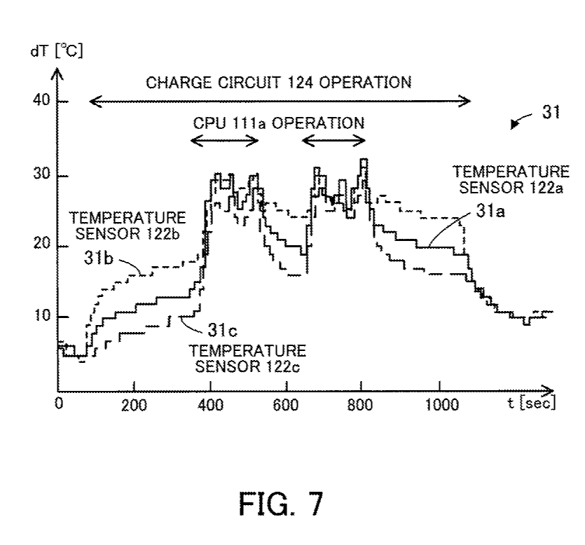

FIG. 7 is a graph illustrating first exemplary change of the relative temperatures of the temperature sensors. A graph 31 indicates change of the relative temperatures (dT) of the temperature sensors 122a, 122b, and 122c relative to the reference point temperature. A curving line 31a indicates the change of the relative temperature of the temperature sensor 122a located near the CPU 111a. A curving line 31b indicates the change of the relative temperature of the temperature sensor 122b located near the charge circuit 124. A curving line 31c indicates the change of the relative temperature of the temperature sensor 122c located near the electric power amplifier 114a.

As illustrated in the graph 31, when the charge circuit 124 starts operating, the relative temperatures of the temperature sensors 122a, 122b, and 122c start rising immediately. Also, when the charge circuit 124 stops operating, the relative temperatures of the temperature sensors 122a, 122b, and 122c start falling immediately. In the same way, when the CPU 111a starts operating, the relative temperatures of the temperature sensors 122a, 122b, and 122c start rising immediately. Also, when the CPU 111a stops operating, the relative temperatures of the temperature sensors 122a, 122b, and 122c start falling immediately.

As described above, the changes of the relative temperatures of the temperature sensors 122a, 122b, and 122c are of a comparatively small delay and a fast response rate in relation to the changes of the heat source temperatures. That is, the thermal time constants of the measured temperatures of the temperature sensors 122a, 122b, and 122c are smaller than that of the surface temperature of the housing 101. Also, variation of response rates is small in the temperature sensors 122a, 122b, and 122c. This is because a substance having a small heat resistance, such as a copper line, is used in the substrate 102, and the heat transfer from the heat sources to the temperature sensors 122a, 122b, and 122c is fast.

Thus, the inverse matrix of H is approximately broken down as in formula (11). This means that hᵢⱼ which is the numerator of the transfer function Hᵢⱼ(s) and 1+sτₕᵢⱼ which is the denominator of the transfer function Hᵢⱼ(s) are separated from each other. The operator of the right side of formula (11) is a Hadamard product which differs from a usual matrix product, and is an operator for calculating a product for each corresponding matrix element. The second term of the right side is an inverse matrix of a matrix that includes heat transfer coefficients hᵢⱼ and does not include a thermal time constant, and is used in estimating the heat source temperatures. The first term of the right side is a matrix that includes one thermal time constant for each heat source, and is used in estimating a surface temperature from the heat source temperatures.

$${H}^{- 1} \approx [ \begin{matrix}1 + s {τ}_{h 1} \\ 1 + s {τ}_{h 2} \\ 1 + s {τ}_{h 3}\end{matrix} ] ∘ {[ \begin{matrix}{h}_{11} & {h}_{12} & {h}_{13} \\ {h}_{21} & {h}_{22} & {h}_{23} \\ {h}_{31} & {h}_{32} & {h}_{33}\end{matrix} ]}^{- 1} \qquad ( 11 )$$

Estimating heat source temperatures by using the second term means assuming a steady state without considering a transient response of a non-steady state. Thereby, the calculation amount for estimating the heat source temperatures is reduced significantly. The heat source temperatures estimated by using the second term disregard the delays of the heat transfer from the heat sources to the temperature sensors 122a, 122b, and 122c, and thus are equivalent to the heat source temperatures of a predetermined time before rather than the heat source temperatures of a time at which the temperatures are measured by the temperature sensors 122a, 122b, and 122c. Thus, the first term is incorporated in the transfer function for estimating the surface temperature from the heat source temperatures. This means that the estimated delays of the heat source temperatures are considered in estimating the surface temperature.

Formula (11) uses a thermal time constant τₕ₁ corresponding to the CPU 111a, a thermal time constant τₕ₂ corresponding to the charge circuit 124, and a thermal time constant τₕ₃ corresponding to the electric power amplifier 114a. Note that the thermal time constants on the substrate 102 are small, and thus the same value may be used for τₕ₁, τₕ₂, and τₕ₃. The value of τₕᵢ is calculated in advance by using the design apparatus 200.

According to the above approximation calculation, the relative temperatures Tₕ₁(s), Tₕ₂(s), and Tₕ₃(s) of the heat sources are calculated by formula (12). The matrix H* is an approximate transfer function on the substrate 102. An element of i-th row and j-th column of the matrix H* is hᵢⱼ which indicates heat transfer that disregards a thermal time constant from an i-th heat source to a j-th temperature sensor. The inverse matrix of H* corresponds to the second term of the right side of formula (11). The inverse matrix of H* is defined as formula (13). Δ is an eigenvalue and is equal to (h₁₁h₂₂−h₁₂h₂₁)h₃₃+(h₁₃h₂₁−h₁₁h₂₃)h₃₂+(h₁₂h₂₃−h₁₃h₂₂)h₃₁. The transient response is not considered, and thus the calculation amount of the product of the inverse matrix of H* and Tₛ₁(s), Tₛ₂(s), and Tₛ₃(s) decreases more significantly than the calculation amount of the product of the inverse matrix of H and Tₛ₁(s), Tₛ₂(s), and Tₛ₃(s).

$$\begin{matrix} [ \begin{matrix}{T}_{h 1} ( s ) \\ {T}_{h 2} ( s ) \\ {T}_{h 3} ( s )\end{matrix} ] = {H}^{* - 1} [ \begin{matrix}{T}_{s 1} ( s ) \\ {T}_{s 2} ( s ) \\ {T}_{s 3} ( s )\end{matrix} ] = {[ \begin{matrix}{h}_{11} & {h}_{12} & {h}_{13} \\ {h}_{21} & {h}_{22} & {h}_{23} \\ {h}_{31} & {h}_{32} & {h}_{33}\end{matrix} ]}^{- 1} [ \begin{matrix}{T}_{s 1} ( s ) \\ {T}_{s 2} ( s ) \\ {T}_{s 3} ( s )\end{matrix} ] & ( 12 ) \\ {H}^{* - 1} = \frac{1}{Δ} [ \begin{matrix}{H}_{22} {H}_{33} - {H}_{23} {H}_{32} & {H}_{13} {H}_{32} - {H}_{12} {H}_{33} & {H}_{12} {H}_{23} - {H}_{13} {H}_{22} \\ {H}_{23} {H}_{31} - {H}_{21} {H}_{33} & {H}_{11} {H}_{33} - {H}_{13} {H}_{31} & {H}_{11} {H}_{23} - {H}_{13} {H}_{21} \\ {H}_{21} {H}_{32} - {H}_{22} {H}_{31} & {H}_{12} {H}_{31} - {H}_{11} {H}_{32} & {H}_{11} {H}_{22} - {H}_{12} {H}_{21}\end{matrix} ] & ( 13 )\end{matrix}$$

Then, according to the above approximation calculation, the relative temperature T_{surf}(s) of the housing 101 is calculated by formula (14) from the estimated Tₕ₁(s), Tₕ₂(s), and Tₕ₃(s). T_{surf}(s) is expressed as a sum of products of G*ᵢ(s) and Tₕᵢ(s). G*ᵢ(s) is a transfer function that expresses the heat transfer from an i-th heat source to the housing 101. gᵢ is a heat transfer coefficient from an i-th heat source to the housing 101; τₕᵢ is a thermal time constant on the substrate 102 of an i-th heat source; and τ_{gi} is a thermal time constant from an i-th heat source to the housing 101. As described above, the thermal time constant τₕᵢ on the substrate 102 is incorporated in the transfer function for estimating the surface temperature from the heat source temperatures, in order to reflect the estimated delays of the heat source temperatures.

$${T}_{surf} ( s ) = {[ \begin{matrix}{G}_{1}^{*} ( s ) \\ {G}_{2}^{*} ( s ) \\ {G}_{3}^{*} ( s )\end{matrix} ]}^{T} [ \begin{matrix}{T}_{h 1} ( s ) \\ {T}_{h 2} ( s ) \\ {T}_{h 3} ( s )\end{matrix} ] \\ where {G}_{i}^{*} ( s ) = \frac{{g}_{i} ( 1 + s {τ}_{hi} )}{1 + s {τ}_{gi}} \qquad ( 14 )$$

Next, a decision method of parameters by the design apparatus 200 will be described. The design apparatus 200 decides the heat transfer coefficients h₁₁, h₁₂, h₁₃, h₂₁, h₂₂, h₂₃, h₃₁, h₃₂, and h₃₃ on the substrate 102. For that purpose, temperatures measured when each heat source is operated independently are acquired by using an actual device of the portable terminal device 100 or sample implementation.

Specifically, the CPU 111a is operated alone while the charge circuit 124 and the electric power amplifier 114a are stopped, in order to acquire the measured temperatures of the temperature sensors 122a, 122b, 122c, and 122d. The design apparatus 200 calculates the relative temperatures of the temperature sensors 122a, 122b, and 122c by subtracting the reference point temperature of the temperature sensor 122d from the measured temperatures of the temperature sensors 122a, 122b, and 122c. Then, the design apparatus 200 calculates h₂₁ and h₃₁ that most appropriately express the relationship between the relative temperature of the temperature sensor 122a and the relative temperatures of the temperature sensors 122b and 122c, by fitting in the time domain. h₁₁ is “1.0”. Note that h₁₁, h₁₂, and h₁₃ may be calculated with reference to directly measured heat source temperature of the CPU 111a, instead of calculating h₂₁ and h₃₁ with reference to the relative temperature of the temperature sensor 122a.

In the same way, the charge circuit 124 is operated alone while the CPU 111a and the electric power amplifier 114a are stopped, in order to acquire the measured temperatures of the temperature sensors 122a, 122b, 122c, and 122d. The design apparatus 200 calculates h₁₂ and h₃₂ that most appropriately express the relationship between the relative temperature of the temperature sensor 122b and the relative temperatures of the temperature sensors 122a and 122c, by fitting in the time domain. h₂₂ is “1.0”. Also, the electric power amplifier 114a is operated alone while the CPU 111a and the charge circuit 124 are stopped, in order to acquire the measured temperatures of the temperature sensors 122a, 122b, 122c, and 122d. The design apparatus 200 calculates h₁₃ and h₂₃ that most appropriately express the relationship between the relative temperature of the temperature sensor 122c and the relative temperatures of the temperature sensors 122a and 122b, by fitting in the time domain. h₃₃ is “1.0”.

That is, the heat transfer coefficients h₁₁, h₁₂, h₁₃, h₂₁, h₂₂, h₂₃, h₃₁, h₃₂, and h₃₃ are decided as in formula (15). Tₛ₁(t), Tₛ₂(t), and Tₛ₃(t) are the measured temperatures of the temperature sensors 122a, 122b, and 122c at a time point t. Tᵣₜ(t) is the measured temperature of the temperature sensor 122d at the time point t and is the reference point temperature at the time point t. Tₕ₁(t), Tₕ₂(t), and Tₕ₃(t) are the heat source temperatures at the time point t. As an example, h₁₁ is equal to 1.0; h₁₂ is equal to 0.6; h₁₃ is equal to 0.6; h₂₁ is equal to 0.7; h₂₂ is equal to 1.0; h₂₃ is equal to 0.4; h₃₁ is equal to 1.0; h₃₂ is equal to 0.3; and h₃₃ is equal to 1.0.

$$[ \begin{matrix}{T}_{s 1} ( t ) - {T}_{rt} ( t ) \\ {T}_{s 2} ( t ) - {T}_{rt} ( t ) \\ {T}_{s 3} ( t ) - {T}_{rt} ( t )\end{matrix} ] = [ \begin{matrix}{h}_{11} & {h}_{12} & {h}_{13} \\ {h}_{21} & {h}_{22} & {h}_{23} \\ {h}_{31} & {h}_{32} & {h}_{33}\end{matrix} ] [ \begin{matrix}{T}_{h 1} ( t ) - {T}_{rt} ( t ) \\ {T}_{h 2} ( t ) - {T}_{rt} ( t ) \\ {T}_{h 3} ( t ) - {T}_{rt} ( t )\end{matrix} ] \qquad ( 15 )$$

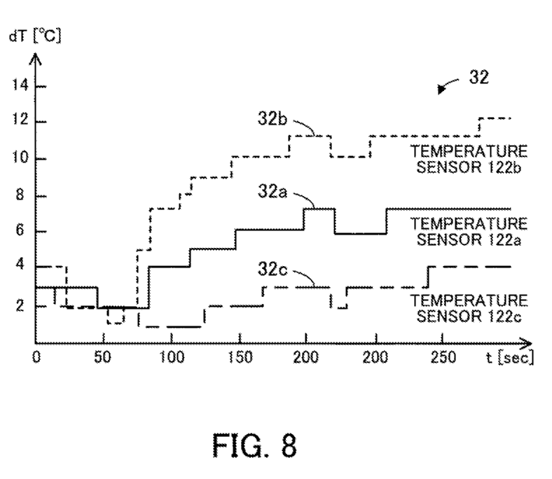

FIG. 8 is a graph illustrating second exemplary change of the relative temperatures of the temperature sensors. A graph 32 indicates the relative temperatures of the temperature sensors 122a, 122b, and 122c, when the charge circuit 124 is operated alone while the CPU 111a and the electric power amplifier 114a are stopped. A curving line 32a indicates the relative temperature of the temperature sensor 122a. A curving line 32b indicates the relative temperature of the temperature sensor 122b. A curving line 32c indicates the relative temperature of the temperature sensor 122c. The temperature sensor 122b is closest to the charge circuit 124, and thus the relative temperature of the temperature sensor 122b is higher than those of the temperature sensors 122a and 122c.

When fitting is performed in the time domain, the difference between the relative temperature of the temperature sensor 122b multiplied by h₁₂ and the relative temperature of the temperature sensor 122a becomes smallest with h₁₂=0.6. Thus, h₁₂ is decided to be 0.6. In the same way, with h₃₂=0.3, the difference between the relative temperature of the temperature sensor 122b multiplied by h₃₂ and the relative temperature of the temperature sensor 122c becomes smallest. Thus, h₃₂ is decided to be 0.3.

Next, the design apparatus 200 decides the heat transfer coefficients g₁, g₂, and g₃, the thermal time constants τₕ₁, τₕ₂, and τₕ₃, and the thermal time constants τ_{g1}, τ_{g2}, and τ_{g3}. For that purpose, temperatures at various positions are measured when each heat source is operated independently, by using an actual device of the portable terminal device 100 or sample implementation. Specifically, the heat source temperatures of the CPU 111a, the charge circuit 124, and the electric power amplifier 114a are measured. Also, a position at which the surface temperature is to be estimated on the surface of the housing 101 is selected, and the surface temperature of the selected position is measured. Two or more positions may be selected as the positions at which the surface temperatures are to be estimated. Also, the reference point temperature measured by the temperature sensor 122d is acquired.

The design apparatus 200 calculates the relative temperatures of the heat sources by subtracting the reference point temperature from the respective heat source temperatures. The design apparatus 200 converts time-series data of the relative temperatures of the heat sources to frequency-domain data by Laplace transform. Also, the design apparatus 200 calculates the relative temperature of the housing 101 by subtracting the reference point temperature from the surface temperature. The design apparatus 200 converts time-series data of the relative temperature of the housing 101 to frequency-domain data by Laplace transform. Then, the design apparatus 200 decides the heat transfer coefficients g₁, g₂, and g₃, the thermal time constants τₕ₁, τₕ₂, and τₕ₃, and the thermal time constants τ_{g1}, τ_{g2}, and τ_{g3} by fitting in the frequency domain. A least squares method is utilized for the fitting in the frequency domain, for example.

That is, the heat transfer coefficients g₁, g₂, and g₃, the thermal time constants τₕ₁, τₕ₂, and τₕ₃, and the thermal time constants τ_{g1}, τ_{g2}, and τ_{g3} are decided as in formula (16). T_{surf}(t) is the surface temperature at a time point t. Tᵣₜ(t) is the measured temperature of the temperature sensor 122d at the time point t and is the reference point temperature at the time point t. Tₕ₁(t), Tₕ₂(t), and Tₕ₃(t) are the heat source temperatures at the time point t.

$$L ( {T}_{surf} ( t ) - {T}_{rt} ( t ) ) = {[ \begin{matrix}{G}_{1}^{*} ( s ) \\ {G}_{2}^{*} ( s ) \\ {G}_{3}^{*} ( s )\end{matrix} ]}^{T} [ \begin{matrix}L ( {T}_{h 1} ( t ) - {T}_{rt} ( t ) ) \\ L ( {T}_{h 2} ( t ) - {T}_{rt} ( t ) ) \\ L ( {T}_{h 3} ( t ) - {T}_{rt} ( t ) )\end{matrix} ] \qquad ( 16 )$$

In this way, the heat transfer coefficients h₁₁, h₁₂, h₁₃, h₂₁, h₂₂, h₂₃, h₃₁, h₃₂, and h₃₃, the heat transfer coefficients g₁, g₂, and g₃, the thermal time constants τₕ₁, τₕ₂, and τₕ₃, and the thermal time constants τ_{g1}, τ_{g2}, and τ_{g3} are decided.

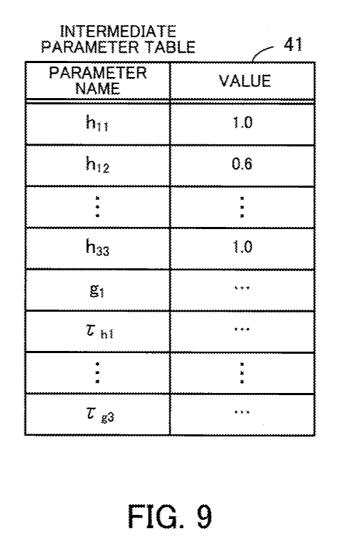

FIG. 9 illustrates an example of an intermediate parameter table. The design apparatus 200 generates an intermediate parameter table 41. The intermediate parameter table 41 associates parameter names and their values. The parameters indicated by the parameter names include the heat transfer coefficients h₁₁, h₁₂, h₁₃, h₂₁, h₂₂, h₂₃, h₃₁, h₃₂, and h₃₃, the heat transfer coefficients g₁, g₂, and g₃, the thermal time constants τₕ₁, τₕ₂, and τₕ₃, and the thermal time constants τ_{g1}, τ_{g2}, and τ_{g3}. These parameters are primary parameters included in the transfer function and may be referred to as intermediate parameters. The parameters included in the estimation equation for estimating the surface temperature are secondary parameters derived from these intermediate parameters. The values decided by the above method are associated with the parameter names.

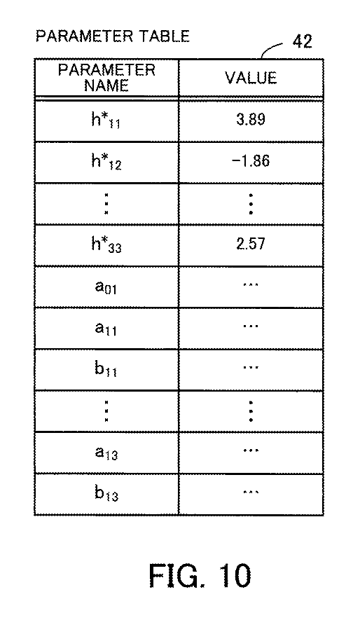

FIG. 10 illustrates an example of a parameter table. The design apparatus 200 generates a parameter table 42 on the basis of the intermediate parameter table 41. The parameter table 42 associates parameter names and values. The parameters indicated by the parameter names include h*₁₁, h*₁₂, h*₁₃, h*₂₁, h*₂₂, h*₂₃, h*₃₁, h*₃₂, h*₃₃, a₀₁, a₁₁, b₁₁, a₀₂, a₁₂, b₁₂, a₀₃, a₁₃, and b₁₃. These parameters are derived from the intermediate parameters of the intermediate parameter table 41. The parameters of the parameter table 42 are stored in the portable terminal device 100.

h*₁₁, h*₁₂, h*₁₃, h*₂₁, h*₂₂, h*₂₃, h*₃₁, h*₃₂, and h*₃₃ are the matrix elements of aforementioned formula (13). h*ᵢⱼ appears at i-th row and j-th column of the inverse matrix of H*. h*₁₁, h*₁₂, h*₁₃, h*₂₁, h*₂₂, h*₂₃, h*₃₁, h*₃₂, and h*₃₃ are derived from the heat transfer coefficients h₁₁, h₁₂, h₁₃, h₂₁, h₂₂, h₂₃, h₃₁, h₃₂, and h₃₃. a₀₁, a₁₁, b₁₁, a₀₂, a₁₂, b₁₂, a₀₃, a₁₃, and b₁₃ are parameters included in the difference equations of the transfer functions G*₁(s), G*₂(s), and G*₃(s), as described later. a₀₁, a₁₁, b₁₁, a₀₂, a₁₂, b₁₂, a₀₃, a₁₃, and b₁₃ are derived from the heat transfer coefficients g₁, g₂, and g₃, the thermal time constants τₕ₁, τₕ₂, and τₕ₃, and the thermal time constants τ_{g1}, τ_{g2}, and τ_{g3}.

Next, an estimation method of a surface temperature by the portable terminal device 100 will be described. The portable terminal device 100 acquires the measured temperatures of the temperature sensors 122a, 122b, 122c, and 122d. Then, the portable terminal device 100 calculates the relative temperatures of the temperature sensors 122a, 122b, and 122c by subtracting the reference point temperature of the temperature sensor 122d from the measured temperatures of the temperature sensors 122a, 122b, and 122c. The portable terminal device 100 estimates the relative temperatures of the CPU 111a, the charge circuit 124, and the electric power amplifier 114a from the relative temperatures of the temperature sensors 122a, 122b, and 122c by formula (17). In this case, h*₁₁, h*₁₂, h*₁₃, h*₂₁, h*₂₂, h*₂₃, h*₃₁, h*₃₂, and h*₃₃ are used as the parameters. The estimation of the relative temperatures of the heat sources is performed in the time domain. Thus, the relative temperatures of the CPU 111a, the charge circuit 124, and the electric power amplifier 114a at a time point are estimated, each time the measured temperatures of the temperature sensors 122a, 122b, 122c, and 122d are acquired.

$$[ \begin{matrix}{T}_{h 1} ( t ) - {T}_{rt} ( t ) \\ {T}_{h 2} ( t ) - {T}_{rt} ( t ) \\ {T}_{h 3} ( t ) - {T}_{rt} ( t )\end{matrix} ] = {[ \begin{matrix}{h}_{11} & {h}_{12} & {h}_{13} \\ {h}_{21} & {h}_{22} & {h}_{23} \\ {h}_{31} & {h}_{32} & {h}_{33}\end{matrix} ]}^{- 1} [ \begin{matrix}{T}_{s 1} ( t ) - {T}_{rt} ( t ) \\ {T}_{s 2} ( t ) - {T}_{rt} ( t ) \\ {T}_{s 3} ( t ) - {T}_{rt} ( t )\end{matrix} ] \qquad ( 17 )$$

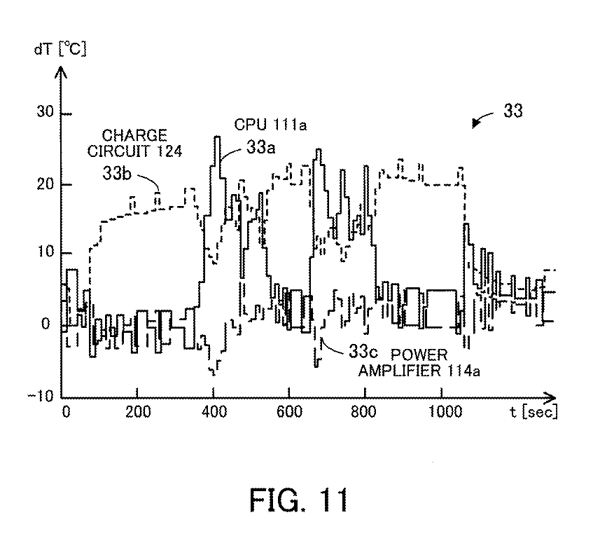

FIG. 11 is a graph indicating an estimation example of the relative temperatures of the heat sources. The graph 33 indicates the relative temperatures of the CPU 111a, the charge circuit 124, and the electric power amplifier 114a which are estimated from the graph 31 of FIG. 7. A curving line 33a indicates an estimated value of the relative temperature of the CPU 111a. A curving line 33b indicates an estimated value of the relative temperature of the charge circuit 124. A curving line 33c indicates an estimated value of the relative temperature of the electric power amplifier 114a.

The portable terminal device 100 estimates the surface temperature at a predetermined position on the surface of the housing 101 on the basis of the estimated relative temperatures of the CPU 111a, the charge circuit 124, and the electric power amplifier 114a. When two or more positions on the surface of the housing 101 are selected, the portable terminal device 100 estimates the surface temperatures of the selected positions. In that case, different transfer functions G*₁(s), G*₂(s), and G*₃(s) are used, depending on the position for estimating the surface temperature. That is, the values of the parameters a₀₁, a₁₁, b₁₁, a₀₂, a₁₂, b₁₂, a₀₃, a₁₃, and b₁₃ are prepared for each position to estimate the surface temperature.

The surface temperature is defined as formula (18). T_{surf}(t) is the surface temperature at a time point t. T_{surf-1}(t) is an increase amount of the surface temperature by the contribution from the CPU 111a, that is, the heat generation of the CPU 111a at the time point t. T_{surf-2}(t) is an increase amount of the surface temperature by the contribution from the charge circuit 124, that is, the heat generation of the charge circuit 124 at the time point t. T_{surf-3}(t) is an increase amount of the surface temperature by the contribution from the electric power amplifier 114a, that is, the heat generation of the electric power amplifier 114a at the time point t. The surface temperature at the time point t is obtained by adding the contribution from the CPU 111a, the contribution from the charge circuit 124, and the contribution from the electric power amplifier 114a to the reference point temperature at the time point t.

$${T}_{surf } ( t ) = {T}_{surf - 1} ( t ) + {T}_{surf - 2} ( t ) + {T}_{surf - 3} ( t ) + {T}_{tr} ( t ) = {L}^{- 1} ( {G}_{1}^{*} ( s ) {T}_{h 1} ( s ) ) + {L}^{- 1} ( {G}_{2}^{*} ( s ) {T}_{h 2} ( s ) ) + {L}^{- 1} ( {G}_{3}^{*} ( s ) {T}_{h 3} ( s ) ) + {T}_{rt} ( t ) \qquad ( 18 )$$

The contribution from the CPU 111a at the time point t is equivalent to what the product of G*₁(s) and Tₕ₁(s) is inverse Laplace transformed. The contribution from the charge circuit 124 at the time point t is equivalent to what the product of G*₂(s) and Tₕ₂(s) is inverse Laplace transformed. The contribution from the electric power amplifier 114a at the time point t is equivalent to what the product of G*₃(s) and Tₕ₃(s) is inverse Laplace transformed. The inverse Laplace transform of the product of G*ᵢ(s) and Tₕᵢ(s) is developed into calculation in the time domain as in formula (19), by using difference equation.

T_{surf-i}(t)=a₀ᵢ(Tₕᵢ(t)−Tᵣₜ(t))+a₁ᵢ(Tₕᵢ(t−Δt)−Tᵣₜ(t−Δt))−b₁ᵢT_{surf-i}(t−Δt) (19)

T_{surf i}(t) is contribution from an i-th heat source at a time point t. The first term of the right side of formula (19) is a relative temperature at the time point t of an i-th heat source. The second term of the right side is a relative temperature of time Δt before of the i-th heat source. Δt is a measurement cycle and is set at approximately 10 seconds, for example. t−Δt means the last measurement time. The third term of the right side is an estimated value of the contribution from the i-th heat source of time Δt before.

The first term is multiplied by a coefficient a₀ᵢ; the second term is multiplied by a coefficient a₁ᵢ; and the third term is multiplied by a coefficient b₁ᵢ. a₀ᵢ, a₁ᵢ, and b₁ᵢ are defined as formula (20) by using gᵢ, τₕᵢ, and τ_{gi}. Thereby, T_{surf 1}(t), T_{surf 2}(t), and T_{surf 3}(t) of formula (18) are calculated.

$${a}_{0 i} = \frac{{g}_{i} ( 2 {τ}_{hi} + Δ t )}{{bb}_{i}} {a}_{1 i} = \frac{{g}_{i} ( - 2 {τ}_{hi} + Δ t )}{{bb}_{i}} {b}_{1 i} = \frac{- 2 {τ}_{gi} + Δ t}{{bb}_{i}} \\ where {bb}_{i} = 2 {τ}_{gi} + Δ t \qquad ( 20 )$$

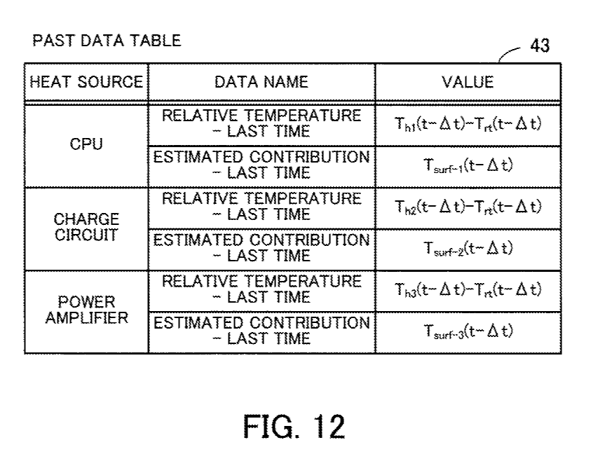

The relative temperature calculated at the last time and the contribution estimated at the last time are recorded for each heat source, in order to use the difference equation of formula (19). FIG. 12 illustrates an example of a past data table. The portable terminal device 100 includes a past data table 43. The past data table 43 associates heat sources, data names, and values. The heat sources include the CPU 111a, the charge circuit 124, and the electric power amplifier 114a. The data names indicate data including a relative temperature of a heat source of the last time and estimated contribution from a heat source of the last time. That is, 6 values are recorded in the past data table 43. The portable terminal device 100 updates the past data table 43, each time the measured temperatures from the temperature sensors 122a, 122b, 122c, and 122d are acquired and the surface temperature is estimated.

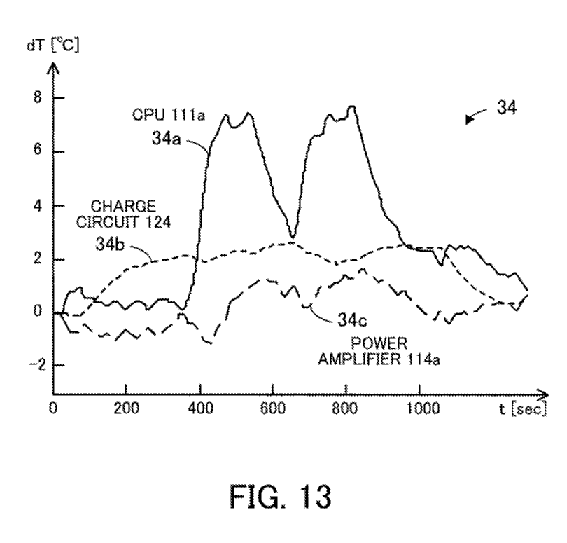

FIG. 13 is a graph indicating an estimation example of the contribution to the housing surface from the heat sources. The graph 34 indicates contribution to increasing surface temperature from the CPU 111a, the charge circuit 124, and the electric power amplifier 114a, which is estimated from the graph 33 of FIG. 11. A curving line 34a indicates contribution to the housing 101 from the CPU 111a. A curving line 34b indicates contribution to the housing 101 from the charge circuit 124. A curving line 34c indicates contribution to the housing 101 from the electric power amplifier 114a.

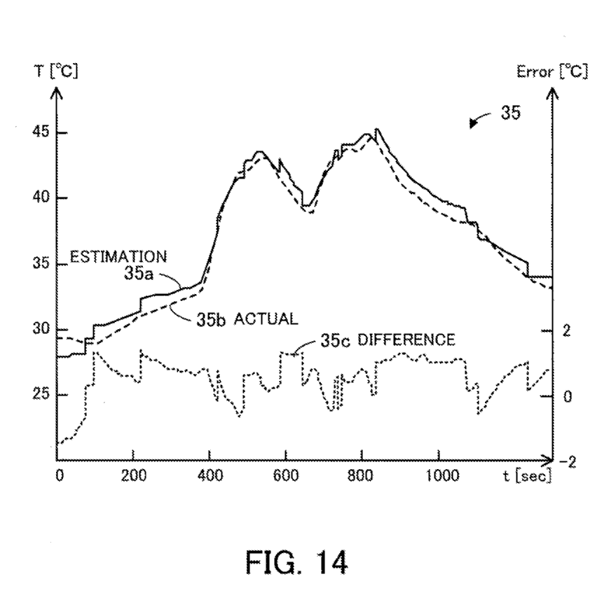

FIG. 14 is a graph indicating an estimation example of the surface temperature. The graph 35 indicates an estimated value of the surface temperature, an actual surface temperature, and a difference between the both. A curving line 35a indicates the estimated value of the surface temperature. The estimated value of the surface temperature is obtained by adding the contribution of the CPU 111a, the charge circuit 124, and the electric power amplifier 114a indicated in the graph 34, to the reference point temperature. A curving line 35b indicates the surface temperature measured by using an actual device of the portable terminal device 100 or sample implementation. A curving line 35c indicates a difference between the curving line 35a and the curving line 35b. According to this experimental example, the absolute value of the difference is within approximately 1° C. as indicated by the curving line 35c.

The portable terminal device 100 controls the heat sources on the basis of the estimated surface temperature. First, the portable terminal device 100 calculates the maximum value (highest prediction reached value) that T_{surf-1}(t) is predicted to reach a certain amount of time or more later, from the temporal change of T_{surf-1}(t) which is the increase amount of the surface temperature due to the heat generation of the CPU 111a. Note that T_{surf-1}(t) corresponds to the temperature index value of the first embodiment.

In the following, the temporal change of T_{surf-1}(t) is expressed by a slope dT_{surf-1}(t) of T_{surf-1}(t) at a time point t. T_{surf 1}(t) and dT_{surf 1}(t) are expressed as formula (21) generally. Tₛₐₜ(t) is the highest prediction reached value of T_{surf-1}(t) calculated at the time point t. The highest prediction reached value is the maximum value of T_{surf-1}(t) estimated under the assumption that the change tendency of the last T_{surf-1}(t) continues. τ_{g1} is a thermal time constant from the CPU 111a to the surface of the housing 101.

$${T}_{surf - 1} ( t ) = {T}_{sat} ( t ) ( 1 - {e}^{\frac{- t}{{τ}_{g 1}}} ) {dT}_{surf - 1} ( t ) = \frac{{T}_{sat} ( t )}{{τ}_{g 1}} {e}^{\frac{- t}{{τ}_{g 1}}} \qquad ( 21 )$$

Tₛₐₜ(t) is expressed by following formula (22), which is obtained from formula (21). The portable terminal device 100 calculates Tₛₐₜ(t) by formula (22). dT_{surf-1}(t) is calculated by dividing the difference between T_{surf 1}(t) and T_{surf-1}(tp) at a time point tp that is a certain amount of time (for example, 1 second, 10 seconds, etc.) before the time point t, by the certain amount of time, for example. When the certain amount of time is 1 second, dT_{surf-1}(t)=T_{surf-1}(t)−T_{surf-1}(tp) is established. When the certain amount of time is Δt seconds (for example, 10 seconds), dT_{surf 1}(t)=(T_{surf 1}(t)−T_{surf 1}(t−Δt))/Δt is established. Note that, when the above time point tp is 1 second before the time point t and the aforementioned Δt (measurement cycle) is 10 seconds, T_{surf-1}(tp) is provisionally calculated at the time point tp in order to obtain dT_{surf-1}(t).

Tₛₐₜ(t)=T_{surf-1}(t)+dT_{surf-1}(t)τ_{g1} (22)

Next, the portable terminal device 100 calculates a rate parameter indicating a target of a decrease rate for decreasing Tₛₐₜ(t) on the basis of the calculated Tₛₐₜ(t) and a threshold value for T_{surf-1}(t).

The threshold value is a temperature index value corresponding to the heat generation amount that is allowable for the CPU 111a. For example, the portable terminal device 100 calculates T_{surf}(t) which is the surface temperature of the housing 101 at the time point t as described above, and decides as the threshold value a value obtained by adding T_{surf-1}(t) to the temperature difference (increase margin amount) between a predetermined allowable temperature (for example, 45° C.) and the calculated T_{surf}(t). In the following, the threshold value at a certain time point t is denoted by Tₘₐₓ(t). Note that, when the surface temperature is estimated for two or more points on the housing 101, the maximum surface temperature is selected.

The rate parameter is a time constant indicating a rate at which Tₛₐₜ(t) converges to Tₘₐₓ(t). The portable terminal device 100 calculates a decrease rate α by dividing Tₘₐₓ(t) by Tₛₐₜ(t) and calculates a rate parameter ατ_{g1} which is a product of α and the thermal time constant τ_{g1} from the CPU 111a to the surface of the housing 101. That is, the time constant indicating the rate for decreasing Tₛₐₜ(t) to Tₘₐₓ(t) is set to τ_{g1}×Tₘₐₓ(t)/Tₛₐₜ(t).

For example, when Tₛₐₜ(t) estimated at a time point t is 40° C., Tₘₐₓ(t) of the time point t is 20° C., and τ_{g1} is 100 seconds, ατ_{g1}=0.5×100=50 seconds is established. Note that the time constant indicates a time that it takes for the change amount to reach (1-e⁻¹)≈63.2% of the target value, for example. Note that the portable terminal device 100 calculates the rate parameter, only when Tₛₐₜ(t) calculated at the time point t is larger than Tₘₐₓ(t).

Next, the portable terminal device 100 controls the clock frequency of the CPU 111a on the basis of the rate parameter and correspondence information that associates a plurality of target values of Tₛₐₜ(t) and a plurality of clock frequencies of the CPU 111a. A certain target value corresponds to the highest reached value reached by T_{surf-1}(t) when the CPU 111a continues operating at a certain clock frequency, for example. The correspondence information is stored in the RAM 112 or the non-volatile memory 113 as a correspondence information table described below, for example.

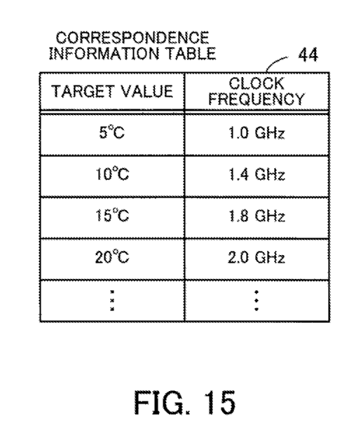

FIG. 15 illustrates an example of a correspondence information table. The correspondence information table 44 associates a plurality of target values of Tₛₐₜ(t) and a plurality of clock frequencies of the CPU 111a.

For example, with a target value=5° C., the CPU 111a operates at a clock frequency 1.0 GHz. With a target value=10° C., the CPU 111a operates at a clock frequency 1.4 GHz. With a target value=15° C., the CPU 111a operates at a clock frequency 1.8 GHz. With a target value=20° C., the CPU 111a operates at a clock frequency 2.0 GHz. Note that, when the clock frequency in the CPU 111a is selectable more finely, it is possible to set the target value more finely.

This correspondence information table 44 may be generated in advance by the portable terminal device 100, for example. The portable terminal device 100 sets T_{surf-1}(tx) obtained at a time point tx at which the CPU 111a has operated for a certain amount of time or more at a certain clock frequency, in the above correspondence information table 44 as the target value corresponding to the certain clock frequency.

The portable terminal device 100 decides the target value of Tₛₐₜ(t) of a predetermined time later on the basis of the rate parameter with reference to the above correspondence information table 44, and sets the clock frequency associated with the decided target value as the upper limit of the clock frequency of the CPU 111a, for example.

For example, the portable terminal device 100 sets the upper limit of the clock frequency of the time point t or later in such a manner that Tₛₐₜ(t) calculated at the time point t decreases to (Tₛₐₜ(t)−Tₘₐₓ(t)) exp(−Δtx/ατ_{g1})+Tₘₐₓ(t) in Δtx seconds.

The portable terminal device 100 decides the target value equivalent to (Tₛₐₜ(t)−Tₘₐₓ(t)) exp(−Δtx/ατ_{g1})+Tₘₐₓ(t) from the correspondence information table 44 and sets the clock frequency corresponding to the target value as the upper limit. When the correspondence information table 44 does not include a target value identical with (Tₛₐₜ(t)−Tₘₐₓ(t)) exp (−Δtx/ατ_{g1})+Tₘₐₓ(t), the clock frequency corresponding to the closest target value is set as the upper limit, for example.

Note that Δtx is Δt multiplied by x (x is an integer equal to or greater than 1), for example. For example, x is equal to 2, and Δtx is equal to 20 seconds. When the value of x is large, an attenuating amount of Tₛₐₜ(t) becomes large, and a smaller upper limit is set for the clock frequency. This reduces the risk of the surface temperature of the housing 101 exceeding an allowable temperature. However, when x is too large, the upper limit of the clock frequency is restricted excessively.

The above process is performed every Δt, and the upper limit of the clock frequency of the CPU 111a is lowered in a phased manner such that the highest prediction reached value Tₛₐₜ attenuates in accordance with the rate parameter calculated at each time.

Note that the portable terminal device 100 may switch on and off the charge circuit 124 on the basis of the estimated surface temperature. For example, when the estimated value of the surface temperature exceeds a predetermined allowable temperature, the portable terminal device 100 stops charging by turning off the charge circuit 124. Also, the portable terminal device 100 may restrict the communication rate of the wireless interface 114 on the basis of the estimated surface temperature. For example, when the estimated value of the surface temperature exceeds a predetermined allowable temperature, the portable terminal device 100 reduces the communication rate of the wireless interface 114.

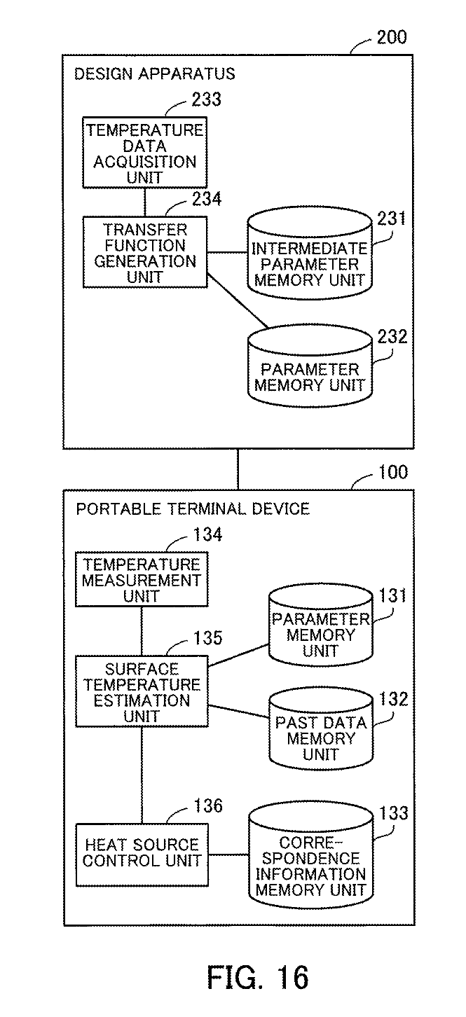

Next, functions of the portable terminal device 100 and the design apparatus 200 will be described. FIG. 16 is a block diagram illustrating exemplary functions of the portable terminal device and the design apparatus.

The portable terminal device 100 includes a parameter memory unit 131, a past data memory unit 132, a correspondence information memory unit 133, a temperature measurement unit 134, a surface temperature estimation unit 135, and a heat source control unit 136. The parameter memory unit 131, the past data memory unit 132, and the correspondence information memory unit 133 are implemented by using a memory region allocated in the RAM 112 or the non-volatile memory 113, for example. The temperature measurement unit 134, the surface temperature estimation unit 135, and the heat source control unit 136 are implemented by using program modules executed by the CPU 111a or the CPU 111b, for example.

The parameter memory unit 131 stores the parameter table 42 illustrated in FIG. 10. The parameter table 42 may be stored in the parameter memory unit 131 at the time of production or shipment of the portable terminal device 100. Also, the parameter table 42 may be stored in the storage medium 120a and distributed to the portable terminal device 100. Also, the parameter table 42 may be distributed to the portable terminal device 100 from a server apparatus via a wireless network.

The past data memory unit 132 stores the past data table 43 illustrated in FIG. 12. The correspondence information memory unit 133 stores the correspondence information table 44 illustrated in FIG. 15. The correspondence information table 44 may also be stored in the correspondence information memory unit 133 at the time of production or shipment of the portable terminal device 100. Also, the correspondence information table 44 may be stored in the storage medium 120a and distributed to the portable terminal device 100. Also, the correspondence information table 44 may be distributed to the portable terminal device 100 from the server apparatus via the wireless network.

The temperature measurement unit 134 periodically acquires the measured temperatures from the temperature sensors 122a, 122b, 122c, and 122d at time intervals Δt (for example, Δt=10 seconds). The surface temperature estimation unit 135 periodically estimates the surface temperature of the housing 101 at time intervals Δt. Specifically, the surface temperature estimation unit 135 acquires the measured temperatures of the temperature sensors 122a, 122b, 122c, and 122d from the temperature measurement unit 134. The surface temperature estimation unit 135 calculates the relative temperatures of the heat sources on the basis of the measured temperatures of the acquired temperature sensors 122a, 122b, 122c, and 122d and the parameter values stored in the parameter memory unit 131.

Also, the surface temperature estimation unit 135 reads out the past data from the past data memory unit 132. Then, the surface temperature estimation unit 135 estimates the surface temperature at a predetermined position on the surface of the housing 101 on the basis of the relative temperatures of the heat sources, the past data, and the parameter values stored in the parameter memory unit 131. The surface temperature estimation unit 135 is also able to calculate the surface temperatures at a plurality of positions by using different parameter values. The surface temperature estimation unit 135 updates the past data stored in the past data memory unit 132, by using a surface temperature estimation result.

The heat source control unit 136 controls components, which are heat sources, of the portable terminal device 100 on the basis of the surface temperature estimated by the surface temperature estimation unit 135. When the surface temperature estimation unit 135 periodically calculates a plurality of surface temperatures, the heat source control unit 136 selects the maximum surface temperature from among the calculated surface temperatures. The heat source control unit 136 compares the surface temperature acquired from the surface temperature estimation unit 135 or the selected surface temperature with a predetermined threshold value. When the surface temperature exceeds the threshold value, the heat source control unit 136 restricts operation levels of the heat sources.

For example, by the aforementioned method, the heat source control unit 136 lowers the upper limit of the clock frequency of the CPU 111a in a phased manner such that the highest prediction reached value Tₛₐₜ attenuates in accordance with the rate parameter. Also, for example, the heat source control unit 136 reduces the communication rate of the wireless interface 114. Also, for example, the heat source control unit 136 stops charging by the charge circuit 124. The CPU 111a instructs the electric power control unit 121 to control the operation levels of the CPU 111a and the wireless interface 114, for example.

The design apparatus 200 includes an intermediate parameter memory unit 231, a parameter memory unit 232, a temperature data acquisition unit 233, and a transfer function generation unit 234. The intermediate parameter memory unit 231 and the parameter memory unit 232 are implemented by using a memory region allocated in the RAM 212 or the HDD 213, for example. The temperature data acquisition unit 233 and the transfer function generation unit 234 are implemented by using program modules executed by the CPU 211, for example.

The intermediate parameter memory unit 231 stores the intermediate parameter table 41 illustrated in FIG. 9. The intermediate parameter table 41 is generated by the design apparatus 200. The parameter memory unit 232 stores the parameter table 42. The parameter table 42 is generated by the design apparatus 200 on the basis of the intermediate parameter table 41. The generated parameter table 42 may be stored in the non-volatile memory 113 of the portable terminal device 100 at the time of production or shipment of the portable terminal device 100. Also, the generated parameter table 42 may be stored in the storage medium 120a and may be distributed via a network.

The temperature data acquisition unit 233 acquires various types of temperatures measured by using an actual device or sample implementation of the portable terminal device 100. The measured temperature may be input into the design apparatus 200 by a user of the design apparatus 200. Also, the measured temperature may be directly acquired from the actual device or the sample implementation of the portable terminal device 100 connected to the design apparatus 200.

The transfer function generation unit 234 decides the values of the intermediate parameters included in the transfer functions by a fitting method, such as a least squares method, by using various types of measured temperatures acquired from the temperature data acquisition unit 233. The transfer function generation unit 234 stores the calculated values of the intermediate parameters in the intermediate parameter memory unit 231. Then, the transfer function generation unit 234 derives the values of the parameters included in the estimation equation for estimating the surface temperature, from the values of the intermediate parameters. The transfer function generation unit 234 stores the calculated parameter values in the parameter memory unit 232. Note that one or two or more positions for estimating the surface temperature are designated by the user of the design apparatus 200.

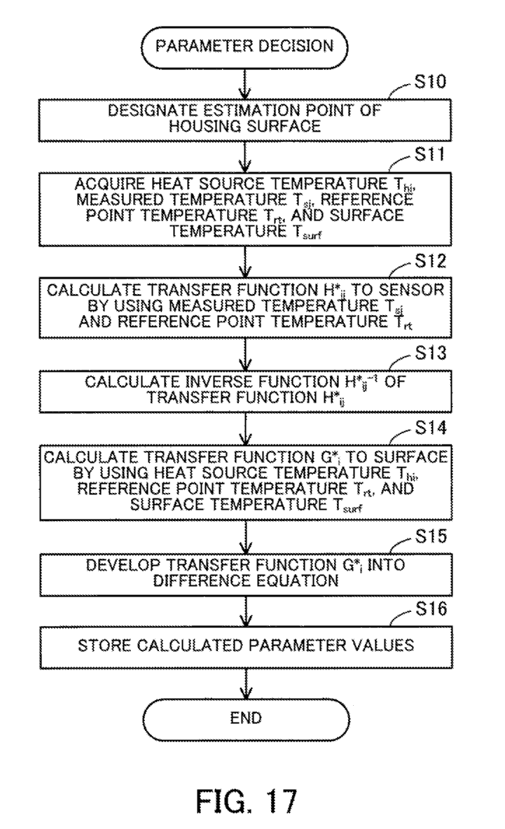

FIG. 17 is a flowchart illustrating an exemplary procedure of parameter decision.

(S10) The transfer function generation unit 234 accepts designation of one or two or more positions (estimation points) on the housing surface for estimating the surface temperature, from the user of the design apparatus 200.

(S11) The temperature data acquisition unit 233 acquires heat source temperatures Tₕᵢ(t), measured temperatures Tₛⱼ(t) measured by the temperature sensors near the heat sources, a reference point temperature Tᵣₜ(t), and a surface temperature T_{surf}(t) of the designated estimation point. At this time, each of the heat sources are operated independently, so that the above various temperatures are measured in temporal sequence.

(S12) The transfer function generation unit 234 calculates transfer functions H*ᵢⱼ=hᵢⱼ from the heat sources to the temperature sensors, by using the measured temperatures Tₛⱼ(t) and the reference point temperature Tᵣₜ(t). The transfer function H*ᵢⱼ=hᵢⱼ is calculated in the time domain by aforementioned formula (15). That is, the transfer function generation unit 234 calculates differences between the measured temperatures Tₛⱼ(t) and the reference point temperature Tᵣₜ(t) for the temperature sensors, and acquires heat transfer coefficients hᵢⱼ of the smallest difference among the temperature sensors.

(S13) The transfer function generation unit 234 calculates an inverse function H*ᵢⱼ¹=h*ᵢⱼ of the transfer function H*ᵢⱼ=hᵢⱼ. The inverse function is calculated from hᵢⱼ by aforementioned formula (13).

(S14) The transfer function generation unit 234 calculates transfer functions G*ᵢ(s) from the heat sources to the estimation point on the housing surface, by using the heat source temperatures Tₕᵢ(t), the reference point temperature Tᵣₜ(t), and the surface temperature T_{surf}(t). That is, the transfer function generation unit 234 decides the heat transfer coefficients gᵢ and the thermal time constants τₕᵢ, τ_{g1i}, and τ_{g2i} included in the transfer functions G*ᵢ(s). The transfer functions G*ᵢ(s) are calculated by a fitting method, such as a least squares method, in the frequency domain by aforementioned formula (16). That is, the transfer function generation unit 234 calculates and Laplace transforms the differences between the heat source temperatures Tₕᵢ(t) and the reference point temperature Tᵣₜ(t) for the heat sources, and calculates and Laplace transforms the differences between the surface temperatures T_{surf}(t) and the reference point temperature Tᵣₜ(t). The transfer function generation unit 234 acquires the heat transfer coefficients gᵢ and the thermal time constants τₕᵢ, τ_{g1i}, and τ_{g2i} of the smallest difference of formula (16).

(S15) The transfer function generation unit 234 develops the transfer functions G*ᵢ(s) into difference equations. That is, the transfer function generation unit 234 calculates a₀ᵢ, a₁ᵢ, a₂ᵢ, b₁ᵢ, and b₂ᵢ of aforementioned formula (20) on the basis of the heat transfer coefficients gᵢ and the thermal time constants τₕᵢ, τ_{g1i}, and τ_{g2i}.

(S16) The transfer function generation unit 234 sets the values of h*ᵢⱼ calculated in step S13 in the parameter table 42. Also, the transfer function generation unit 234 sets the values of a₀₁, a₁₁, a₂₁, b₁₁, and b₂₁ calculated in step S15 in the parameter table 42.

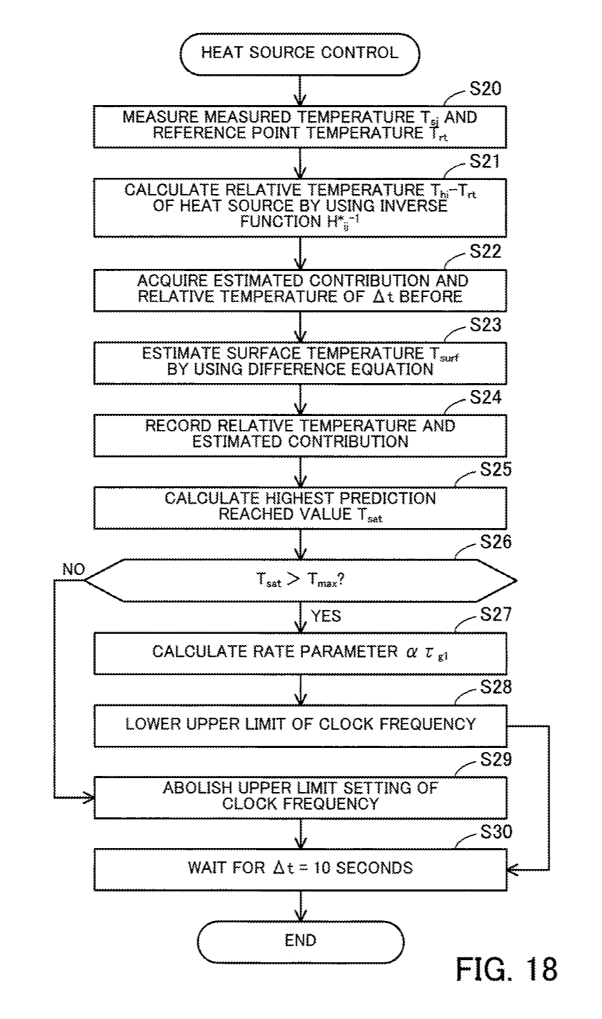

FIG. 18 is a flowchart illustrating an exemplary procedure of heat source control.

(S20) The temperature measurement unit 134 acquires the temperatures Tₛⱼ(t) measured by the temperature sensors 122a, 122b, and 122c near the heat sources. Also, the temperature measurement unit 134 acquires the reference point temperature Tᵣₜ(t) measured by the temperature sensor 122d.

(S21) The surface temperature estimation unit 135 calculates the relative temperatures Tₕᵢ(t)−Tᵣₜ(t) of the heat sources by using the measured temperatures Tₛⱼ(t), the reference point temperature Tᵣₜ(t), and the inverse function H*ᵢⱼ⁻¹=h*ᵢⱼ of the transfer function H*ᵢⱼ. The relative temperatures of the heat sources are calculated in the time domain by aforementioned formula (17) by using the values of h*ᵢⱼ set in the parameter table 42. That is, the surface temperature estimation unit 135 calculates the differences between the measured temperatures Tₛⱼ(t) and the reference point temperature Tᵣₜ(t) for the temperature sensors, and calculates Tₕᵢ(t)−Tᵣₜ(t) by product-sum operation with h*ᵢⱼ.

(S22) The surface temperature estimation unit 135 reads out the past data from the past data table 43. That is, the surface temperature estimation unit 135 reads out the relative temperatures (differences between the heat source temperatures and the reference point temperature) calculated time Δt before for the heat sources. Also, the surface temperature estimation unit 135 reads out the estimated contribution to the housing surface which is calculated time Δt before, for each heat source.

(S23) The surface temperature estimation unit 135 estimates the surface temperature T_{surf}(t) from the relative temperatures Tₕᵢ(t)−Tᵣₜ(t) of the heat sources calculated in step S21, by using the difference equations. The surface temperature T_{surf}(t) is calculated by aforementioned formula (18). That is, the surface temperature estimation unit 135 calculates the estimated contribution T_{surf-i}(t) at a time point t, from the relative temperature at the time point t calculated in step S21 and the past data read out in step S22, by aforementioned formula (19) for each heat source. At this time, the surface temperature estimation unit 135 uses the values of a₀ᵢ, a₁ᵢ, and b₁ᵢ set in the parameter table 42. Then, the surface temperature estimation unit 135 calculates the surface temperature T_{surf}(t) by adding the estimated contribution T_{surf-i}(t) of the heat sources to the reference point temperature Tᵣₜ(t) at the time point t.

(S24) The surface temperature estimation unit 135 records the relative temperatures of the heat sources which are calculated in step S21 in the past data table 43 as the relative temperatures of time Δt before. Also, the surface temperature estimation unit 135 records the estimated contribution of each heat source which is calculated in step S23 in the past data table 43 as the estimated contribution of time Δt before. The above steps S22 to S24 are executed for each estimation point, when two or more estimation points for estimating the surface temperature are designated.

(S25) The heat source control unit 136 calculates a highest prediction reached value Tₛₐₜ(t) of the contribution to the surface temperature from the CPU 111a in accordance with formula (22). Also, the heat source control unit 136 calculates a threshold value Tₘₐₓ(t) that is allowable for the contribution to the surface temperature from the CPU 111a. Note that the surface temperature estimation unit 135 may calculate T_{surf-1}(t−1) one second before the calculation of Tₛₐₜ(t). Also, the heat source control unit 136 may calculate Tₛₐₜ(t) by using T_{surf-1}(t−Δt) calculated Δt seconds before.

(S26) The heat source control unit 136 compares the calculated highest prediction reached value Tₛₐₜ(t) and the calculated threshold value Tₘₐₓ(t) to determine whether Tₛₐₜ(t) exceeds Tₘₐₓ(t). If Tₛₐₜ(t) exceeds Tₘₐₓ(t), the process proceeds to step S27. In other cases, the process proceeds to step S29.

(S27) The heat source control unit 136 calculates the decrease rate α=Tₘₐₓ(t)/Tₛₐₜ(t) and then calculates the rate parameter ατ_{g1} which is a product of a and the thermal time constant τ_{g1} from the CPU 111a to the surface of the housing 101.

(S28) The heat source control unit 136 lowers the upper limit of the clock frequency on the basis of the rate parameter and the correspondence information table 44 illustrated in FIG. 15. The set upper limit is lower than the highest clock frequency that the CPU 111a is able to reach physically. Thereby, the CPU 111a is able to change the clock frequency only within a range of the set upper limit or below, in order to restrict the computing power and the heat generation amount of the CPU 111a. Note that the clock frequency of the CPU 111a dynamically changes according to the load of the CPU 111a, for example.

The heat source control unit 136 sets the upper limit of the clock frequency, in such a manner that Tₛₐₜ(t) at a time point t decreases to (Tₛₐₜ(t)−Tₘₐₓ(t)) exp(−Δtx/ατ_{g1})+Tₘₐₓ(t) in Δtx seconds. For example, when Δt=10 seconds and x=2, the upper limit of the clock frequency is set in such a manner that Tₛₐₜ(t) becomes (Tₛₐₜ(t)−Tₘₐₓ(t)) exp(−20/ατ_{g1})+Tₘₐₓ(t) in 20 seconds. In this case, the heat source control unit 136 selects the closest value to (Tₛₐₜ(t)−Tₘₐₓ(t)) exp(−20/ατ_{g1})+Tₘₐₓ(t), among the target values that are set in the correspondence information table 44, for example. Then, the heat source control unit 136 sets the upper limit at the clock frequency corresponding to the selected target value.

As described above, the clock frequency of the CPU 111a is restricted to reduce the heat generation amount. Note that the heat source control unit 136 may further control other heat sources, such as the charge circuit 124 and the electric power amplifier 114a, to reduce the heat generation amount. Then, the process proceeds to step S30.

(S29) The heat source control unit 136 abolishes the upper limit setting of the clock frequency of the CPU 111a. Thereby, the upper limit of the clock frequency of the CPU 111a becomes identical with the highest clock frequency that is achievable physically. The CPU 111a is able to freely change the clock frequency within a physically achievable range, and the computing power and the heat generation amount of the CPU 111a are not restricted. Note that the heat source control unit 136 may make the upper limit of the clock frequency higher than that of the present moment, instead of abolishing the upper limit setting of the clock frequency.

(S30) The temperature measurement unit 134 and the surface temperature estimation unit 135 wait for the time Δt (for example, 10 seconds). After the time Δt elapses, one cycle of heat source control ends, and the process is executed again from step S20.

By the above process, Tₛₐₜ(t) and T_{surf-1}(t) change as in the following, for example.

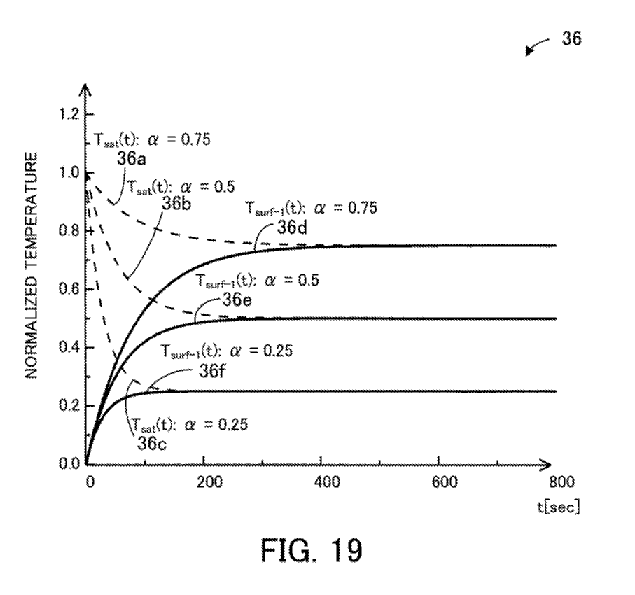

FIG. 19 is a graph illustrating exemplary change of Tₛₐₜ(t) and T_{surf-1}(t) corresponding to a plurality of values of α. In the following, the values of Tₛₐₜ(t) and T_{surf-1}(t) are normalized in such a manner that the highest prediction reached value calculated at a certain time point becomes 1.0, in some cases.

In the graph 36, a curving line 36a indicates change of the normalized Tₛₐₜ(t) attenuated from 1 to α=0.75. A curving line 36b indicates change of the normalized Tₛₐₜ(t) attenuated from 1 to α=0.5. A curving line 36c indicates change of the normalized Tₛₐₜ(t) attenuated from 1 to α=0.25.

Also, in the graph 36, a curving line 36d corresponds to the curving line 36a and indicates change of normalized T_{surf-1}(t) when α=0.75. A curving line 36e corresponds to the curving line 36b and indicates change of normalized T_{surf-1}(t) when α=0.5. A curving line 36f corresponds to the curving line 36c and indicates change of normalized T_{surf-1}(t) when α=0.25.

By the aforementioned control of the clock frequency, Tₛₐₜ(t) attenuates at a decrease rate based on ατ_{g1} and converges to α. Along with this, T_{surf-1}(t) converges to α. As described below, Tₛₐₜ(t) is controlled to be attenuated at the rate of the time constant ατ_{g1}, so that it is possible to increase the upper limit of the clock frequency of the CPU 111a up to a limit that prevents overshoot of T_{surf-1}(t).

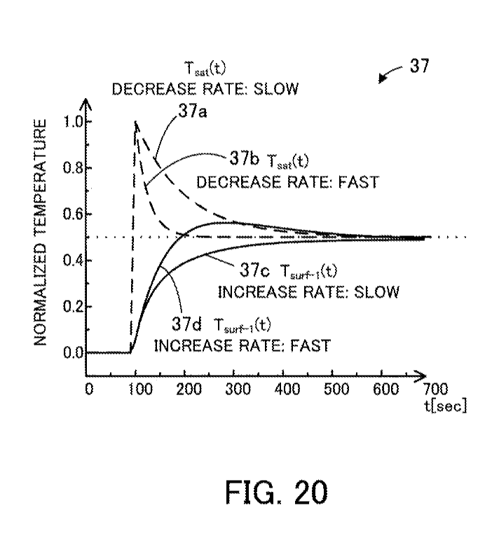

FIG. 20 is a graph illustrating exemplary change of Tₛₐₜ(t) and T_{surf-1}(t) when the rate parameter is not used. In a graph 37, curving lines 37a and 37b indicate change of the normalized Tₛₐₜ(t) attenuated from 1 to α=0.5. α=0.5 corresponds to the threshold value Tₘₐₓ(t). The decrease rate of Tₛₐₜ(t) indicated by the curving line 37a is slower than the decrease rate indicated by the rate parameter ατ_{g1}. On the other hand, the decrease rate of Tₛₐₜ(t) indicated by the curving line 37b is faster than the decrease rate indicated by the rate parameter ατ_{g1}. Also, curving lines 37c and 37d indicate the change of normalized T_{surf-1}(t). The curving line 37c corresponds to the curving line 37b, and the curving line 37d corresponds to the curving line 37a.

When the clock frequency is decreased rapidly, the decrease rate of Tₛₐₜ(t) becomes fast like the curving line 37b, and the increase rate of T_{surf-1}(t) becomes too slow like the curving line 37c. Hence, despite the margin to the threshold value, the CPU 111a is operated at a clock frequency that is too low, possibly decreasing the performance of the CPU 111a. On the other hand, when the clock frequency is decreased at a slow rate, the decrease rate of Tₛₐₜ(t) becomes slow like the curving line 37a, and the increase rate of T_{surf-1}(t) becomes fast like the curving line 37d. Hence, “overshoot”, in which T_{surf 1}(t) temporarily exceeds the threshold value like the curving line 37d, occurs in some cases.

In contrast, as illustrated in FIG. 19, the performance of the CPU 111a is maximized within a range in which the surface temperature does not overshoot, by lowering the upper limit of the clock frequency in a phased manner such that Tₛₐₜ(t) decreases at a specific rate. The inventors of the present application discovered that the performance of the CPU 111a is maximized when the time constant for decreasing Tₛₐₜ(t) is ατ_{g1}. Thus, with the portable terminal device 100, it is possible to maximize the performance of the CPU 111a to the limit that prevents the overshoot of the surface temperature.

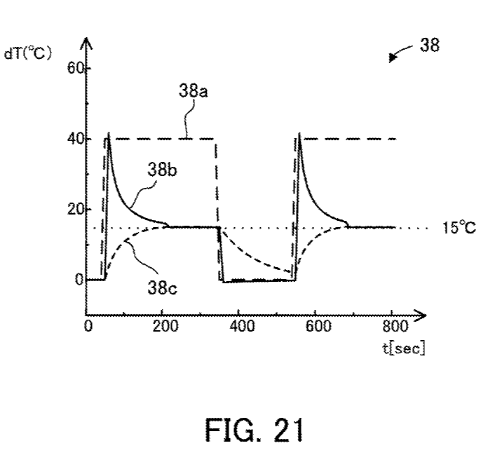

FIG. 21 illustrates a control example of the surface temperature of the housing. The vertical axis represents a relative temperature dT [° C.] which is an increase amount relative to a reference point temperature, and the horizontal axis represents time t [sec]. In a graph 38, a curving line 38a indicates temporal change of the highest prediction reached temperature when the clock frequency of the CPU 111a is not restricted (for example, when the CPU 111a continues operating at the highest clock frequency). A curving line 38b indicates temporal change of the highest prediction reached temperature when the clock frequency is restricted by the aforementioned method. A curving line 38c indicates temporal change of the contribution to the surface temperature from the CPU 111a when the clock frequency is restricted by the aforementioned method.

In the example of FIG. 21, the reference point temperature is 30° C. Also, the allowable surface temperature of the housing 101 is 45° C., and the threshold value of the contribution to the surface temperature from the CPU 111a is 15° C. When the load of the CPU 111a increases rapidly, it is expected that the contribution to the surface temperature from the CPU 111a increases to 40° C. shortly (the highest prediction reached temperature is 40° C.), like the curving line 38a. If this goes on, the surface temperature of the housing 101 exceeds the allowable temperature.

In contrast, the heat source control unit 136 restricts the clock frequency in such a manner that Tₛₐₜ(t) decreases like the curving line 38b, and thereby the surface temperature of the housing 101 converges to 15° C. like the curving line 38c. Also, the performance of the CPU 111a is prevented from deteriorating due to excessive frequency restriction, by setting the time constant for decreasing Tₛₐₜ(t) to ατ_{g1}.

As described above, in the portable terminal device 100 of the second embodiment, the temperature difference T_{surf-1}(t) generated by the heat generation of the CPU 111a, which is part of the difference between the surface temperature of the housing 101 and the reference temperature, is calculated as a temperature index value of the surface temperature of the housing 101. Then, Tₛₐₜ(t) is calculated as the highest prediction reached value that T_{surf-1}(t) is predicted to reach over time. Also, the rate parameter ατ_{g1} indicating the target of the decrease rate for decreasing Tₛₐₜ(t) is calculated on the basis of Tₛₐₜ(t) calculated at a time point t and the threshold value Tₘₐₓ(t). Then, the upper limit of the clock frequency of the CPU 111a is restricted on the basis of the calculated ατ_{g1} and the correspondence information that associates a plurality of target values of Tₛₐₜ(t) and a plurality of clock frequencies.

Thereby, the clock frequency is needless to be restricted excessively as compared with a case in which the upper limit of the clock frequency is lowered rapidly to a level corresponding to Tₘₐₓ(t) when Tₛₐₜ(t) exceeds Tₘₐₓ(t). That is, if the heat capacity between the CPU 111a and the surface of the housing 101 is taken into consideration, even when the clock frequency temporarily exceeds the level corresponding to Tₘₐₓ(t) in a transient state, the subsequent T_{surf 1}(t) does not exceed Tₘₐₓ(t) in some cases, and there is much time to converge the clock frequency. The restriction of the clock frequency is made gradual by utilizing this transient state, and thereby the clock frequency is needless to be restricted excessively, and the performance of the CPU 111a is prevented from decreasing.

Note that, as described above, the information processing of the first embodiment is achieved by causing the electronic device 1 to execute a program. The information processing of the second embodiment is achieved by causing the portable terminal device 100 and the design apparatus 200 to execute programs.

The programs may be recorded in a computer-readable storage medium (for example, the storage medium 120a or 223). The storage medium may be a magnetic disk, an optical disc, a magneto-optical disk, or a semiconductor memory, for example. The magnetic disk includes an FD and an HDD. The optical disc includes a CD, a CD-R(Recordable)/RW(ReWritable), a DVD, and a DVD-R/RW. The programs may be stored in a portable storage medium for the purpose of distribution. In that case, the programs may be copied and executed in another storage medium (for example, the non-volatile memory 113 or the HDD 213) from the portable storage medium.

In one aspect, the performance of the processor is prevented from deteriorating in temperature control.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. An electronic device comprising:
a memory;
a temperature sensor;
a housing that contains the temperature sensor; and
a controller connected to the memory, contained in the housing, including a processor capable of operating at a plurality of clock frequencies, and configured to perform a procedure including:
calculating a temperature index value of a temperature of a surface of the housing by using the temperature sensor, and calculating a prediction reached value that the temperature index value is predicted to reach a certain amount of time or more later from change of the calculated temperature index value,
calculating a rate parameter indicating a target of a decrease rate for decreasing the prediction reached value, based on the prediction reached value calculated at a certain time point and a threshold value of the temperature index value, and
controlling a clock frequency of the processor before the certain amount of time elapses, based on the calculated rate parameter and correspondence information that associates a plurality of target values of the prediction reached value and the plurality of clock frequencies.

2. The electronic device according to claim 1, wherein:
the controller lowers the clock frequency of the processor in a phased manner such that the prediction reached value decreases at a decrease rate according to the rate parameter.

3. The electronic device according to claim 1, wherein:
the controller calculates the rate parameter based on the prediction reached value calculated at the certain time point, the threshold value, and a delay parameter indicating delay of heat transfer from the processor to the surface of the housing.

4. The electronic device according to claim 1, further comprising:
a plurality of temperature sensors including the temperature sensor,
wherein the temperature of the surface of the housing is dependent on heat generation of a plurality of heat sources including the processor, and
the controller calculates a temperature difference generated by the heat generation of the processor, which is part of a temperature difference between the temperature of the surface of the housing and a reference temperature, as the temperature index value by using the temperature sensors.

5. The electronic device according to claim 4, wherein
the controller calculates the temperature of the surface of the housing and decides the threshold value based on a difference between a predetermined allowable temperature and the calculated temperature of the surface of the housing and the temperature index value of the certain time point.

6. A processor control method comprising:
calculating, by a controller in an electronic device, a temperature index value of a temperature of a housing surface of the electronic device by using a temperature sensor in the electronic device, and calculating a prediction reached value that the temperature index value is predicted to reach a certain amount of time or more later from change of the calculated temperature index value;
calculating, by the controller, a rate parameter indicating a target of a decrease rate for decreasing the prediction reached value, based on the prediction reached value calculated at a certain time point and a threshold value of the temperature index value; and
controlling, by the controller, a clock frequency of a processor in the electronic device before the certain amount of time elapses, based on the calculated rate parameter and correspondence information that associates a plurality of target values of the prediction reached value and a plurality of clock frequencies of the processor.

7. A non-transitory computer-readable storage medium storing a processor control program that causes a computer in an electronic device to perform a procedure comprising:
calculating a temperature index value of a temperature of a housing surface of the electronic device by using a temperature sensor in the electronic device, and calculating a prediction reached value that the temperature index value is predicted to reach a certain amount of time or more later from change of the calculated temperature index value;
calculating a rate parameter indicating a target of a decrease rate for decreasing the prediction reached value, based on the prediction reached value calculated at a certain time point and a threshold value of the temperature index value; and
controlling a clock frequency of a processor in the electronic device before the certain amount of time elapses, based on the calculated rate parameter and correspondence information that associates a plurality of target values of the prediction reached value and a plurality of clock frequencies of the processor.
